(19) United States
(12) Patent Application Publication
(10) Pub. No.: US 2025/0221146 A1
(43) Pub. Date: Jul. 3, 2025

(54) DISPLAY DEVICE, LIGHT EMITTING DEVICE, AND LIGHTING DEVICE

(71) Applicant: Sharp Display Technology Corporation, Kameyama City, Mie (JP)

(72) Inventor: YUSUKE SAKAKIBARA, Sakai City, Osaka (JP)

(21) Appl. No.: 18/850,699

(22) PCT Filed: May 13, 2022
(86) PCT No.: PCT/JP2022/020168

§ 371 Date: Sep. 25, 2024

(51) Int. Cl. H10K 50/115; H10K 59/35

(52) U.S. Cl. CPC H10K 50/115; H10K 59/353

(57) ABSTRACT

A display device includes a display region including a first region including at least a part of a central portion of the display region and a second region including at least a part of end portions of the display region, a first light-emitting element provided in the first region, and a second light-emitting element provided in the second region, in which each of the first light-emitting element and the second light-emitting element includes a first electrode and a second electrode, and a nanoparticle layer positioned between the first electrode and the second electrode, the nanoparticle layer containing nanoparticles, and a concentration of halogen atoms contained in a first layer which is the nanoparticle layer of the first light-emitting element is higher than a concentration of halogen atoms contained in a second layer which is the nanoparticle layer of the second light-emitting element.

### TECHNICAL FIELD

The disclosure relates to a display device, a light-emitting device, and a lighting device.

### BACKGROUND ART

In recent years, various display devices including light-emitting elements provided with a nanoparticle layer including nanoparticles as a part of layers of the function layers including a light-emitting layer are developed, and in particular, a display device provided with a quantum dot light-emitting diode (QLED), or an organic light-emitting diode (OLED) attracts a great deal of attention from perspectives such as the capability to achieve lower power consumption, a slimmer design, higher picture quality, and the like.

In addition, a light-emitting device including a wavelength conversion layer with a light-emitting layer including quantum dots and a lighting device including a light-emitting region with a light-emitting layer including quantum dots are actively developed from the perspective of achieving low power consumption, reduced thickness, and the like.

It is known that, when nanoparticles such as quantum dots are used as a part of layers of function layers including a light-emitting layer, if the nanoparticles are used in combination with a halogen ligand, the luminous efficiency can be improved compared with nanoparticles used in combination with a ligand other than a halogen ligand.

For example, NPL 1 describes that the carrier balance and luminous efficiency can be improved by forming an amount of halogen ligands included in a quantum dot layer provided in a QLED to have a gradient in the layering direction of the quantum dot layer.

### CITATION LIST

### Non Patent Literature

NPL 1: Taehyung Kim, Kwang-Hee Kim, Sungwoo Kim, Seon-Myeong Choi, Hyosook Jang, Hong-Kyu Seo, Heejae Lee, Dae-Young Chung1, Eunjoo Jang “Efficient and stable blue quantum dot light-emitting diode”, Nature, Vol. 586, pp. 385-389 (15 Oct. 2020).

### SUMMARY

### Technical Problem

The inventors of the disclosure find that a layer including nanoparticles, such as quantum dots and a halogen ligand at a relatively high concentration is easily damaged at a site where mechanical stress occurs.

Although the QLED described in NPL 1 is formed such that the amount of the halogen ligand has a gradient in the layering direction of the quantum dot layer, it includes a halogen ligand at a relatively high concentration, so, when such a QLED is provided over the entire display region of the display device, there is a problem that the QLED is damaged in a region close to an end portion of the display region where mechanical stress easily occurs.

light-emitting devices and lighting devices including a layer including nanoparticles such as quantum dots and a halogen ligand at a relatively high concentration also suffer from the problem that they are easily damaged at sites where mechanical stress occurs.

On the other hand, although damage to a display device, a light-emitting device, and a lighting device including light-emitting elements can be reduced if the amount of the halogen ligand used together with nanoparticles such as quantum dots is reduced, there is a problem of luminous efficiency significantly deteriorating.

An aspect of the disclosure has been made in view of the above problems, and an object thereof is to provide a display device, a light-emitting device, and a lighting device that can achieve compatibility of reduced damage at sites where mechanical stress occurs with luminous efficiency.

### Solution to Problem

In order to solve the above-described problems, a display device according to the disclosure includes a display region including a first region including at least a part of a central portion of the display region and a second region including at least a part of an end portion of the display region, a first light-emitting element provided in the first region, and a second light-emitting element provided in the second region, in which each of the first light-emitting element and the second light-emitting element includes a first electrode and a second electrode, and a nanoparticle layer positioned between the first electrode and the second electrode, the nanoparticle layer including nanoparticles, and a concentration of halogen atoms included in a first layer which is the nanoparticle layer of the first light-emitting element is higher than a concentration of halogen atoms included in a second layer which is the nanoparticle layer of the second light-emitting element.

In order to solve the above-described problems, a display device according to the disclosure includes a display region including a first region including at least a part of a central portion of the display region and a second region including at least a part of an end portion of the display region, a first light-emitting element provided in the first region, and a second light-emitting element provided in the second region, in which each of the first light-emitting element and the second light-emitting element includes a first electrode and a second electrode, and a nanoparticle layer positioned between the first electrode and the second electrode, the nanoparticle layer including nanoparticles, a central position in a thickness of a maximum film thickness portion of each of a first layer which is the nanoparticle layer of the first light-emitting element and a second layer which is the nanoparticle layer of the second light-emitting element is set as a reference position, the number of portions of a third layer formed directly above the first layer, the portions intruding into the first layer at or below the reference position, is set as a first number, the number of portions of a fourth layer formed directly above the second layer, the portions intruding into the second layer at or below the reference position, is set as a second number, and the first number per unit length of the first layer is greater than the second number per unit length of the second layer.

In order to solve the above-described problems, a display device according to the disclosure includes a display region including a first region including at least a part of a central portion of the display region and a second region including at least a part of an end portion of the display region, a first light-emitting element provided in the first region, and a second light-emitting element provided in the second region, in which each of the first light-emitting element and the second light-emitting element includes a first electrode and a second electrode, and a nanoparticle layer positioned between the first electrode and the second electrode, the nanoparticle layer including nanoparticles, a central position in a thickness of a maximum film thickness portion of each of a third layer formed directly above the first layer which is the nanoparticle layer of the first light-emitting element and a fourth layer formed directly above the second which is the nanoparticle layer of the second light-emitting element is set as a reference position, the number of portions of the first layer intruding into the third layer at or beyond the reference position is set as a first number, the number of portions of the second layer intruding into the fourth layer at or beyond the reference position is set as a second number, and the first number per unit length of the first layer is greater than the second number per unit length of the second layer.

In order to solve the above-described problems, a light-emitting device according to the disclosure includes a wavelength conversion layer including a first region including at least a part of a central portion of a wavelength conversion region and a second region including at least a part of an end portion of the wavelength conversion region, and a light-emitting portion that is provided on a first surface side of the wavelength conversion layer and emits light incident on the wavelength conversion layer, in which a concentration of halogen atoms included in a light-emitting layer including quantum dots of the first region is higher than a concentration of halogen atoms included in a light-emitting layer including quantum dots of the second region.

In order to solve the above-described problems, a lighting device of the disclosure includes a light-emitting region having a light-emitting surface in a size of 100 cm² or greater and including a first region including at least a part of a central portion of the light-emitting region and a second region including at least a part of an end portion of the light-emitting region, in which the light-emitting region includes a first electrode and a second electrode, and a light-emitting layer provided between the first electrode and the second electrode, the light-emitting layer including quantum dots, and a concentration of halogen atoms included in the first region is higher than a concentration of halogen atoms included in the second region.

### Advantageous Effects of Disclosure

According to one aspect of the disclosure, a display device, a light-emitting device, and a lighting device that can achieve compatibility of reduced damage at a site where mechanical stress occurs with luminous efficiency can be provided.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a first region in a display region of the display device according to the first embodiment.

FIG. 3(a) is a cross-sectional view illustrating a schematic configuration of a red light-emitting element provided in the first region among display regions of the display device according to the first embodiment, and FIG. 3(b) is a cross-sectional view illustrating a schematic configuration of a red light-emitting element provided in a second region among the display regions of the display device according to the first embodiment.

FIGS. 4(a) and 4(b) are views illustrating an example of a phenomenon that may occur around an aggregate of quantum dots of the red light-emitting element provided in the first region among the display regions of the display device according to the first embodiment.

FIG. 5 is a graph for describing deflection due to the weight of a substrate provided in the display device according to the first embodiment.

FIG. 6 is a diagram for describing a site where stress is likely to occur in a case that there are a substrate provided in the display device of the first embodiment and a layer having a thermal expansion coefficient different from that of the substrate, the layer being provided on the substrate.

FIG. 7 is a diagram for describing a coverage proportion of a quantum dot with respect to a halogen ligand in a light-emitting layer included in a light-emitting element included in each subpixel of the display device according to the first embodiment.

FIGS. 8(a) to 8(o) are diagrams illustrating an example of a step of forming quantum dot layers in a lift-off method, which is part of a step of forming the light-emitting layers included in the light-emitting elements included in the respective subpixels of the display device according to the first embodiment.

FIGS. 9(a) to 9(c) are diagrams illustrating an example of a step of incorporating a halogen ligand into only the first region among the display regions of the display device according to the first embodiment.

FIGS. 10(a) to 10(d) are diagrams illustrating another example of the step of incorporating a halogen ligand into only the first region among the display regions of the display device according to the first embodiment.

FIG. 11 is a diagram illustrating an image signal converter, subpixel circuits, and various wires provided in the display device according to the first embodiment.

FIG. 12 is a diagram illustrating an example of a subpixel circuit provided in the display device according to the first embodiment.

FIGS. 13(a) to 13(d) are plan views illustrating an example of a display device according to a second embodiment.

FIG. 14 is a plan view illustrating an example of a display device according to a third embodiment.

FIG. 15 is a plan view illustrating an example of a display device according to a fourth embodiment.

FIGS. 16(a) to 16(c) are diagrams for describing a method of manufacturing a display device according to a fifth embodiment in which various display devices can be obtained by changing a cutting position with respect to the same mother substrate.

FIG. 17(a) is a plan view illustrating a schematic configuration of a wavelength conversion layer provided in a light-emitting device according to a sixth embodiment, and FIG. 17(b) is a cross-sectional view illustrating a schematic configuration of the light-emitting device according to the sixth embodiment.

FIG. 18(a) is a plan view illustrating a schematic configuration of a light-emitting region provided in a lighting device according to a seventh embodiment, and FIG. 18(b) is a cross-sectional view illustrating a schematic configuration of the lighting device according to the seventh embodiment.

### DESCRIPTION OF EMBODIMENTS

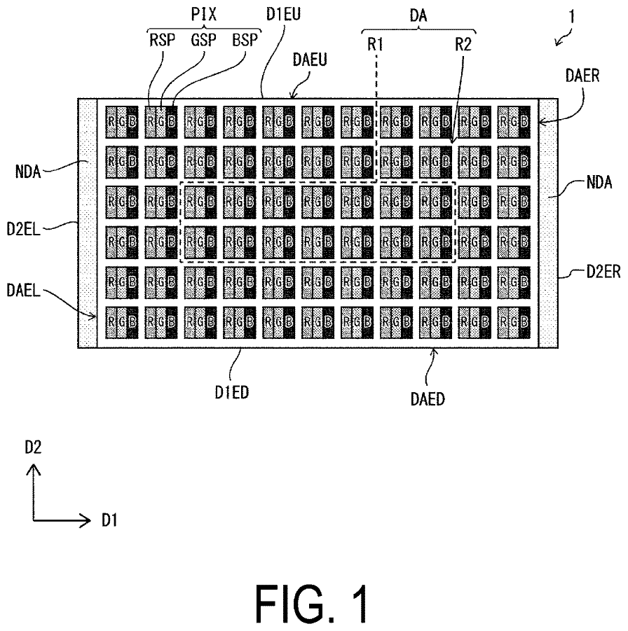

Embodiments of the disclosure will be described as below with reference to FIGS. 1 to 18. Hereinafter, for convenience of description, configurations having the same functions as those described in a specific embodiment are denoted by the same reference signs, and descriptions thereof will be omitted.

### First Embodiment

FIG. 1 is a plan view illustrating a schematic configuration of a display device 1 according to a first embodiment.

As illustrated in FIG. 1, the display device 1 includes a display region DA including an upper end portion DAEU, a right end portion DAER, a lower end portion DAED, and a left end portion DAEL. Although the example in which the display device 1 includes the display regions DA including the above-described four end portions is described in the present embodiment, the disclosure is not limited thereto. A shape of each display region DA can be determined as appropriate, and for example, the display region DA may be formed in an n-sided polygonal shape (n is a natural number of 3 or greater) or a circular shape. If the display region DA is formed in an n-sided polygonal shape (n is a natural number of 3 or greater), the display region DA includes n (n is a natural number of 3 or greater) end portions, and if the display region DA is formed in a circular shape, the display region DA includes one curved end portion.

A plurality of pixels PIX are provided in the display region DA of the display device 1, and each pixel PIX includes a red subpixel RSP, a green subpixel GSP, and a blue subpixel BSP. In the present embodiment, although an example in which one pixel PIX includes the red subpixel RSP, the green subpixel GSP, and the blue subpixel BSP is described, the disclosure is not limited thereto. For example, one pixel PIX may further include a subpixel of another color in addition to the red subpixel RSP, the green subpixel GSP, and the blue subpixel BSP.

The red subpixel RSP provided in the display region DA of the display device 1 includes a red light-emitting element that emit red light, the green subpixel GSP provided in the display region DA of the display device 1 includes a green light-emitting element that emits green light, and the blue subpixel BSP provided in the display region DA of the display device 1 includes a blue light-emitting element that emits blue light.

Although a case in which the display region DA of the display device 1 includes a first region R1 including the entire central portion of the display region DA and a second region R2 including all end portions of the display region DA, and the second region R2 surrounds the first region R1 in a frame shape will be exemplified in the present embodiment, the disclosure is not limited thereto. For example, the first region R1 may include at least a part of the central portion of the display region DA, and the second region R2 may include at least some of the end portions of the display region DA.

As will be described later, each of the red light-emitting element, the green light-emitting element, and the blue light-emitting element provided in the first region R1 and the second region R2 of the display region DA includes a nanoparticle layer including nanoparticles positioned between first and second electrodes. Further, nanoparticles refer to particles (dots) each having a maximum width less than 1000 nm. A shape of the nanoparticles is not particularly limited as long as it is within a range in which having the above maximum width is satisfied, and the shape is not limited to a spherical three-dimensional shape (circular cross-sectional shape). The shape of the nanoparticles may be, for example, a polygonal cross-sectional shape, a rod-shaped three-dimensional shape, a branch-shaped three-dimensional shape, or a three-dimensional shape having unevenness on the surface thereof, or a combination thereof.

Although a case in which a concentration of halogen atoms included in the nanoparticle layers provided in each of the red light-emitting element, the green light-emitting element, and the blue light-emitting element provided in the first region R1 is higher than a concentration of halogen atoms included in the nanoparticle layer provided in each of the red light-emitting element, the green light-emitting element, and the blue light-emitting element provided in the second region R2 is exemplified in the present embodiment, the disclosure is not limited thereto. For example, a concentration of halogen atoms included in the nanoparticle layer provided in one or more light-emitting elements (first light-emitting elements) of the red, green, and blue light-emitting elements provided in the first region R1 is only required to be higher than a concentration of halogen atoms included in the nanoparticle layer provided in one or more light-emitting elements (second light-emitting elements) of the red, green, and blue light-emitting elements provided in the second region R2. Furthermore, for example, a light-emitting element (first light-emitting element) including a nanoparticle layer provided in the first region R1 and having a higher concentration of halogen atoms and a light-emitting element (second light-emitting element) including a nanoparticle layer provided in the second region R2 and having a lower concentration of halogen atoms may be light-emitting elements that emit light of the same color.

Although a case in which the nanoparticle layer including nanoparticles is a light-emitting layer including quantum dots is exemplified in the present embodiment, the disclosure is not limited thereto. For example, the nanoparticle layer including nanoparticles may be a charge transfer layer such as a hole injection layer, a hole transport layer, an electron injection layer, and an electron transport layer. When the nanoparticle layer including nanoparticles is a hole injection layer or a hole transport layer, nanoparticles with hole transportability can be used as the nanoparticles, the nanoparticles with hole transportability are preferably nanoparticles including at least one of Ni, Mg, Mo, Cu, Co, Cr, or Ti, and for example, NiO particles can be suitably used as the nanoparticles with hole transportability. In addition, when the nanoparticle layer including nanoparticles is an electron injection layer or an electron transport layer, nanoparticles with electron transportability can be used as the nanoparticles, nanoparticles with electron transportability are preferably nanoparticles including at least one of Zn, Mg, Ti, Si, Sn, W, Ta, Ba, Zr, Al, Y, or Hf, and for example, ZnO particles can be suitably used as nanoparticles with electron transportability.

As illustrated in FIG. 1, the display device 1 includes a frame portion NDA. Since the frame portion NDA is a non-display region, no pixels PIX including subpixels of the respective colors are provided.

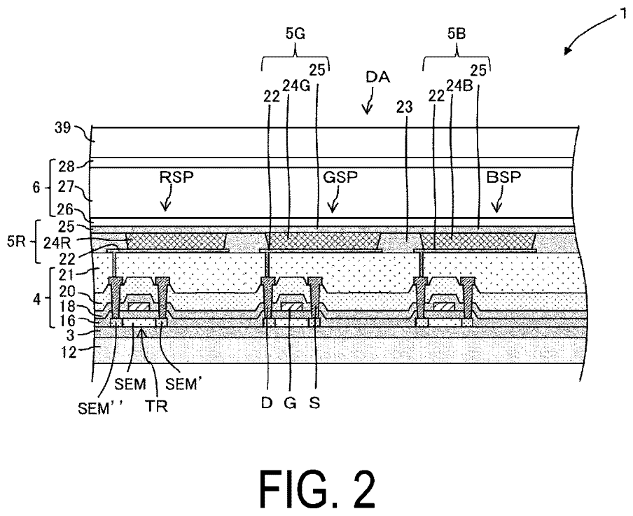

FIG. 2 is a cross-sectional view illustrating a schematic configuration of the first region R1 in the display region DA of the display device 1 according to the first embodiment. Although a schematic configuration of the second region R2 in the display region DA of the display device 1 according to the first embodiment is the same as the schematic configuration of the first region R1 illustrated in FIG. 2, a noticeable difference is that the concentration of halogen atoms included in the nanoparticle layer provided in each of the red light-emitting element 5R, the green light-emitting element 5G, and the blue light-emitting element 5B provided in the first region R1 is higher than the concentration of halogen atoms included in the nanoparticle layer provided in each of the red light-emitting element, the green light-emitting element, and the blue light-emitting element provided in the second region R2.

As illustrated in FIG. 2, in the display region DA of the display device 1, a barrier layer 3, a thin film transistor layer 4 including transistors TR, the red light-emitting element 5R, the green light-emitting element 5G, the blue light-emitting element 5B, a bank 23, a sealing layer 6, and a function film 39 are provided on a substrate 12 in this order from the substrate 12 side.

The blue subpixel BSP included in the first region R1 of the display region DA of the display device 1 includes a blue light-emitting element 5B, a green subpixel GSP included in the first region R1 of the display region DA of the display device 1 includes a green light-emitting element 5G, and a red subpixel RSP included in the first region R1 of the display region DA of the display device 1 includes a red light-emitting element 5R.

The substrate 12 may be, for example, a resin substrate made of a resin material such as a polyimide, or may be a glass substrate. In the present embodiment, the display device 1 is a flexible display device, and thus a case will be described as an example in which a resin substrate made of the resin material such as a polyimide is used as the substrate 12; however, the disclosure is not limited thereto. In a case that the display device 1 is a non-flexible display device, the glass substrate may be used as the substrate 12.

The barrier layer 3 is a layer that inhibits foreign matter, such as water and oxygen, from entering the transistor TR, the red light-emitting element 5R, the green light-emitting element 5G, and the blue light-emitting element 5B, and can be formed of, for example, a silicon oxide film, a silicon nitride film, or a silicon oxynitride film, or a layered film thereof formed by using a chemical vapor deposition (CVD) method.

The transistor TR portion of the thin film transistor layer 4 including the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21, and a portion other than the transistor TR portion of the thin film transistor layer 4 including the transistor TR includes the inorganic insulating film 16, the inorganic insulating film 18, the inorganic insulating film 20, and the flattening film 21.

The semiconductor films SEM, SEM′, and SEM″ may be formed of low-temperature polysilicon (LTPS) or an oxide semiconductor (for example, an In—Ga—Zn—O based semiconductor), for example. Although a case in which the transistor TR has a top gate structure is exemplified in the present embodiment, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, and copper.

The inorganic insulating film 16, the inorganic insulating film 18, and the inorganic insulating film 20 can be formed of, for example, a silicon oxide film, a silicon nitride film, or a silicon oxynitride film, or a layered film thereof, formed by using the CVD method.

The flattening film 21 can be formed of coatable organic materials such as a polyimide and acrylic material.

The red light-emitting element 5R included in the red subpixel RSP includes an anode, which is a first electrode 22 that is an upper layer overlying the flattening film 21, a function layer 24R including a red light-emitting layer, and a cathode, which is a second electrode 25, the green light-emitting element 5G included in the green subpixel GSP includes an anode, which is the first electrode 22 that is an upper layer overlying the flattening film 21, a function layer 24G including the green light-emitting layer, and a cathode, which is the second electrode 25, and the blue light-emitting element 5B included in the blue subpixel BSP includes an anode, which is the first electrode 22 that is an upper layer overlying the flattening film 21, a function layer 24B including the blue light-emitting layer, and a cathode, which is the second electrode 25. Note that the bank 23 having insulating properties covering the edge of the anode serving as the first electrode 22 can be formed, for example, by applying an organic material, such as a polyimide or acrylic material, and then patterning the organic material by photolithography.

Although a case in which the red light-emitting element 5R, the green light-emitting element 5G, and the blue light-emitting element 5B are in a conventional structure is exemplified in the present embodiment, the disclosure is not limited to this example, and the red light-emitting element 5R, the green light-emitting element 5G, and the blue light-emitting element 5B may be in an inverted-layered structure. The red light-emitting element 5R in the conventional structure includes the first electrode 22 serving as the anode and the second electrode 25 serving as the cathode provided as an upper layer above the first electrode 22, and the function layer 24R including the red light-emitting layer provided between the first electrode 22 serving as the anode and the second electrode 25 serving as the cathode can be formed by layering, for example, a hole injection layer, a hole transport layer, a red light-emitting layer, an electron transport layer, and an electron injection layer in this order from the first electrode 22 side. Of the hole injection layer, the hole transport layer, the electron transport layer, and the electron injection layer in the function layer 24R including the red light-emitting layer, other than the red light-emitting layer, one or more layers may be omitted as appropriate. Although a case in which the function layer 24R including the red light-emitting layer is formed by layering the hole transport layer, the red light-emitting layer, and the electron transport layer in this order from the anode side, the anode being the first electrode 22 is exemplified in the present embodiment, the disclosure is not limited thereto. The green light-emitting element 5G in the conventional structure includes the first electrode 22 serving as the anode and the second electrode 25 serving as the cathode provided as an upper layer above the first electrode 22, and the function layer 24G including the green light-emitting layer provided between the first electrode 22 serving as the anode and the second electrode 25 serving as the cathode can be formed by layering, for example, a hole injection layer, a hole transport layer, a green light-emitting layer, an electron transport layer, and an electron injection layer in this order from the first electrode 22 side. Of the hole injection layer, the hole transport layer, the electron transport layer, and the electron injection layer in the function layer 24G including the green light-emitting layer, other than the green light-emitting layer, one or more layers may be omitted as appropriate. Although a case in which the function layer 24G including the green light-emitting layer is formed by layering the hole transport layer, the green light-emitting layer, and the electron transport layer in this order from the anode side, the anode being the first electrode 22 is exemplified in the present embodiment, the disclosure is not limited thereto. The blue light-emitting element 5B in the conventional structure includes the first electrode 22 serving as the anode and the second electrode 25 serving as the cathode provided as an upper layer above the first electrode 22, and the function layer 24B including the blue light-emitting layer provided between the first electrode 22 serving as the anode and the second electrode 25 serving as the cathode can be formed by layering, for example, a hole injection layer, a hole transport layer, a blue light-emitting layer, an electron transport layer, and an electron injection layer in this order from the first electrode 22 side. Of the hole injection layer, the hole transport layer, the electron transport layer, and the electron injection layer in the function layer 24B including the blue light-emitting layer, other than the blue light-emitting layer, one or more layers may be omitted as appropriate. Although a case in which the function layer 24B including the blue light-emitting layer is formed by layering the hole transport layer, the blue light-emitting layer, and the electron transport layer in this order from the anode side, the anode being the first electrode 22, is exemplified in the present embodiment, the disclosure is not limited thereto.

Although not illustrated, the red light-emitting element in the inverted-layered structure includes the first electrode serving as the cathode and the second electrode serving as the anode provided as an upper layer above the first electrode, and the function layer including the red light-emitting layer provided between the first electrode serving as the cathode and the second electrode serving as the anode can be formed by layering, for example, an electron injection layer, an electron transport layer, a red light-emitting layer, a hole transport layer, and a hole injection layer in this order from the first electrode side. Of the electron injection layer, the electron transport layer, the hole transport layer, and the hole injection layer in the function layer including the red light-emitting layer, other than the red light-emitting layer, one or more layers may be omitted as appropriate. The green light-emitting element in the inverted-layered structure includes the first electrode serving as the cathode and the second electrode serving as the anode provided as an upper layer above the first electrode, and the function layer including the green light-emitting layer provided between the first electrode serving as the cathode and the second electrode serving as the anode can be formed by layering, for example, an electron injection layer, an electron transport layer, a green light-emitting layer, a hole transport layer, and a hole injection layer in this order from the first electrode side. Of the electron injection layer, the electron transport layer, the hole transport layer, and the hole injection layer in the function layer including the green light-emitting layer, other than the green light-emitting layer, one or more layers may be omitted as appropriate. The blue light-emitting element in the inverted-layered structure includes the first electrode serving as the cathode and the second electrode serving as the anode provided as an upper layer above the first electrode, and the function layer including the blue light-emitting layer provided between the first electrode serving as the cathode and the second electrode serving as the anode can be formed by layering, for example, an electron injection layer, an electron transport layer, a blue light-emitting layer, a hole transport layer, and a hole injection layer in this order from the first electrode side. Of the electron injection layer, the electron transport layer, the hole transport layer, and the hole injection layer in the function layer including the blue light-emitting layer, other than the blue light-emitting layer, one or more layers may be omitted as appropriate.

Although a case in which poly[(9,9-dioctylfluorenyl-2,7-diyl)-co-(4,4′-(N-(4-sec-butylphenyl))diphenylamine)] (TFB) that is a material not including nanoparticles, for example, is used as the hole transport layer included in each of the function layer 24R including the red light-emitting layer, the function layer 24G including the green light-emitting layer, and the function layer 24B including the blue light-emitting layer is exemplified in the present embodiment, the disclosure is not limited thereto, and, for example, N,N′-bis(4-butylphenyl)-N,N′-bis(phenyl)-benzidine (poly-TPD), polyvinylcarbazole (PVK) or the like may be used. In addition, as the hole transport layer included in each of the function layer 24R including the red light-emitting layer, the function layer 24G including the green light-emitting layer, and the function layer 24B including the blue light-emitting layer, the above-described nanoparticles with hole transportability may be used.

Although a case in which 2,2′,2″-(1,3,5-benzinetriyl)-tris(1-phenyl-1-H-benzimidazole) (TPBi) that is a material not including nanoparticles, for example, is used as the electron transport layer included in each of the function layer 24R including the red light-emitting layer, the function layer 24G including the green light-emitting layer, and the function layer 24B including the blue light-emitting layer is exemplified in the present embodiment, the disclosure is not limited thereto, and nanoparticles with the electron transportability described above may be used.

In addition, although a case in which the function layer 24R including the red light-emitting layer, the function layer 24G including the green light-emitting layer, and the function layer 24B including the blue light-emitting layer each include the hole transport layer formed using the same material in the same process, and the electron transport layer formed using the same material in the same process is exemplified in the present embodiment, the disclosure is not limited thereto. For example, the function layer 24R including the red light-emitting layer, the function layer 24G including the green light-emitting layer, and the function layer 24B including the blue light-emitting layer each may further include at least one of the hole injection layer formed using the same material in the same process, or the electron injection layer formed using the same material in the same process. In addition, for example, the hole transport layers included respectively in the function layers 24R, 24G, and 24B may be formed of materials different from each other, and for example, the hole transport layers included respectively in two function layers of the function layers 24R, 24G, and 24B may be formed of the same material in the same process, and only the hole transport layer included in the remaining one function layer may be formed of a different material in another process. In addition, for example, the electron transport layers included respectively in the function layers 24R, 24G, and 24B may be formed of materials different from each other, and for example, the electron transport layers included respectively in two function layers of the function layers 24R, 24G, and 24B may be formed of the same material in the same process, and only the electron transport layer included in the remaining one function layer may be formed of a different material in another process. In addition, for example, the hole injection layers included respectively in the function layers 24R, 24G, and 24B may be formed of materials different from each other, and for example, the hole injection layers each included in two function layers of the function layers 24R, 24G, and 24B may be formed of the same material in the same process, and only the hole injection layer included in the remaining one function layer may be formed of a different material in another process. In addition, for example, the electron injection layers included respectively in the function layers 24R, 24G, and 24B may be formed of materials different from each other, and for example, the electron injection layers each included in two function layers of the function layers 24R, 24G, and 24B may be formed of the same material in the same process, and only the electron injection layer included in the remaining one function layer may be formed of a different material in another process.

Although a case in which the red light-emitting element 5R, the green light-emitting element 5G, and the blue light-emitting element 5B are all quantum dot light-emitting diodes (QLEDs) is exemplified in the present embodiment, the disclosure is not necessary to be limited to this example, and at least one of the red light-emitting element 5R, the green light-emitting element 5G, and the blue light-emitting element 5B may be a QLED. For example, when one of the red light-emitting element 5R, the green light-emitting element 5G, and the blue light-emitting element 5B is a QLED, the remaining two may be organic light-emitting diodes (OLEDs), and for example, when two of the red light-emitting element 5R, the green light-emitting element 5G, and the blue light-emitting element 5B are QLEDs, the remaining one may be an OLED.

In addition, when at least one of the hole injection layer, the hole transport layer, the electron transport layer, and the electron injection layer other than each color light-emitting layer among the function layers 24R, 24G, and 24B including each color light-emitting layer is a nanoparticle layer including nanoparticles, the red light-emitting element 5R, the green light-emitting element 5G, and the blue light-emitting element 5B may be an organic light-emitting diode (OLED) including an organic light-emitting layer not including nanoparticles as a light-emitting layer.

As in the present embodiment, when all of the red light-emitting element 5R, the green light-emitting element 5G, and the blue light-emitting element 5B are QLEDs, the light-emitting layers included in the respective color light-emitting elements include quantum dots. The quantum dots may have, for example, a core structure, a core/shell structure, a core/shell/shell structure, or a shell structure with a continuously varying ratio. Note that the shell may completely cover the core, or may partially cover the core. The core may be composed of, for example, Si, C, or the like in a case of a unitary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AIGS or the like in a case of a quaternary system. The shell can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AIP, or the like in a case of a ternary system.

Note that a quantum dot is a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

A control circuit including the transistors TR each of which controls the red light-emitting element 5R, the green light-emitting element 5G, and the blue light-emitting element 5B is provided in the thin film transistor layer 4 including the transistors TR corresponding to the red subpixel RSP, the green subpixel GSP, and the blue subpixel BSP. Note that the control circuit including the transistors TR provided corresponding to the red subpixel RSP, the green subpixel GSP, and the blue subpixel BSP and the light-emitting elements are collectively referred to as a subpixel circuit.

The red light-emitting element 5R, the green light-emitting element 5G, and the blue light-emitting element 5B illustrated in FIG. 2 may be a top-emitting type or a bottom-emitting type. Since the red light-emitting element 5R, the green light-emitting element 5G, and the blue light-emitting element 5B have the conventional structures in which the second electrode 25 serving as the cathode is disposed as an upper layer above the first electrode 22 serving as the anode, in order to realize the top-emitting type, the first electrode 22 serving as the anode may be formed of an electrode material that reflects visible light and the second electrode 25 serving as the cathode may be formed of an electrode material that allows visible light to pass through, and in order to realize the bottom-emitting type, the first electrode 22 serving as the anode may be formed of an electrode material that allows visible light to pass through and the second electrode 25 serving as the cathode may be formed of an electrode material that reflects visible light. On the other hand, when the red light-emitting element, the green light-emitting element, and the blue light-emitting element have the inverted-layered structures in which the second electrode serving as the anode is disposed as an upper layer above the first electrode serving as the cathode, in order to realize the top-emitting type, the first electrode serving as the cathode may be formed of an electrode material that reflects visible light and the second electrode serving as the anode may be formed of an electrode material that allows visible light to pass through, and in order to realize the bottom-emitting type, the first electrode serving as the cathode may be formed of an electrode material that allows visible light to pass through and the second electrode serving as the anode may be formed of an electrode material that reflects visible light.

The electrode material that reflects visible light is not particularly limited as long as the material can reflect visible light and has electrical conductivity, and examples thereof include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

A typical electrode forming method may be used as a film formation method of the first electrode 22 and the second electrode 25, and examples thereof include physical vapor deposition (PVD) such as vacuum vapor deposition, a sputtering method, electron beam (EB) vapor deposition, and an ion plating method, or chemical vapor deposition (CVD). Furthermore, a method of patterning the first electrode 22 and the second electrode 25 is not particularly limited as long as the method is capable of precisely forming a desired pattern, and specific examples thereof include a photolithography method and an ink-jet method.

The sealing layer 6 is a transparent film and, for example, may be composed of an inorganic sealing film 26 for covering the second electrode 25, an organic film 27 that is an upper layer overlying the inorganic sealing film 26, and an inorganic sealing film 28 that is an upper layer overlying the organic film 27. The sealing layer 6 inhibits foreign matters such as water and oxygen from intruding into the red light-emitting element 5R, the green light-emitting element 5G, and the blue light-emitting element 5B.

The inorganic sealing film 26 and the inorganic sealing film 28 are both inorganic films and may be composed of, for example, a silicon oxide film, a silicon nitride film, a silicon oxynitride film, or a layered film thereof, formed by using the CVD method. The organic film 27 is a transparent organic film having a flattening effect, and may be composed of a coatable organic material such as an acrylic material, for example. The organic film 27 may be formed by an ink-jet method, for example. Although the case in which the sealing layer 6 is formed of two layers of an inorganic film and one layer of an organic film provided between the two layers of the inorganic film is exemplified in the present embodiment, the layering order of the two layers of the inorganic film and the one layer of the organic film is not limited thereto. Furthermore, the sealing layer 6 may be composed of only an inorganic film, may be composed of only an organic film, may be composed of one layer of an inorganic film and two layers of an organic film, or may be composed of two or more layers of an inorganic film and two or more layers of an organic film.

The function film 39 is a film with at least one of an optical compensation function, a touch sensor function, and a protection function, for example.

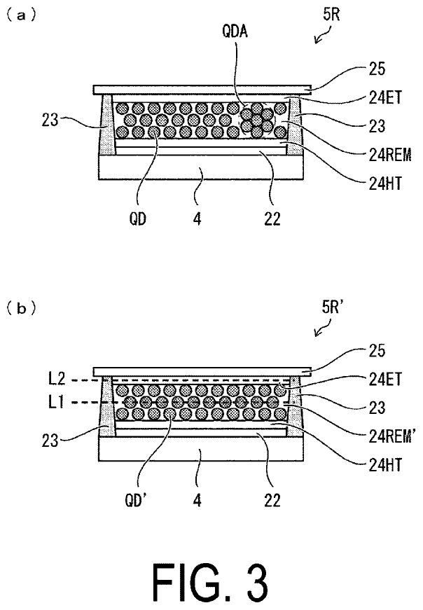

(a) of FIG. 3 is a cross-sectional view illustrating a schematic configuration of the red light-emitting element 5R provided in the first region R1 in the display region DA of the display device 1 according to the first embodiment, and (b) of FIG. 3 is a cross-sectional view illustrating a schematic configuration of a red light-emitting element 5R′ provided in the second region R2 in the display region DA of the display device 1 according to the first embodiment. Although not illustrated, each of the green light-emitting element 5G and the blue light-emitting element 5B provided in the first region R1 in the display region DA of the display device 1 of the first embodiment has the same configuration as that of the red light-emitting element 5R illustrated in (a) of FIG. 3 except that the emission color of the light-emitting layer is different, and each of the green light-emitting element and the blue light-emitting element provided in the second region R2 in the display region DA of the display device 1 of the first embodiment has the same configuration as that of the red light-emitting element 5R′ illustrated in (b) of FIG. 3 except that the emission color of the light-emitting layer is different.

The red light-emitting element 5R illustrated in (a) of FIG. 3 is provided on the thin film transistor layer 4 including the transistor TR illustrated in FIG. 2, and includes the first electrode 22 as an anode, the second electrode 25 as a cathode, and the function layer 24R including a red light-emitting layer provided between the first electrode 22 and the second electrode 25. The function layer 24R including the red light-emitting layer is configured by layering a hole transport layer 24HT, a red light-emitting layer 24REM, and an electron transport layer 24ET in order from the first electrode 22 side.

The red light-emitting layer 24REM includes a ligand including halogen atoms and quantum dots. A ligand is a compound having a coordination function, and when both a ligand and quantum dots are included, it is considered that the ligand is coordinated to the quantum dots. The quantum dots QD illustrated in (a) of FIG. 3 mean quantum dots to which a ligand including halogen atoms is coordinated.

The ligand including halogen atoms means, for example, a ligand including F, Cl, Br, or I being halogen atoms, and is attracted to the surface of the positively charged quantum dots (QDs) in an anionic state such as F⁻, Cl⁻, Br⁻, or I⁻. It is preferable that a ligand including halogen atoms be coordinated to the quantum dots because stability and electron injection properties are improved, and among ligands, one composed of fluorine having strong coordination force to quantum dots is more preferable. Although a case in which a ligand composed of fluorine is used as a ligand composed of halogen atoms is exemplified in the present embodiment considering the strong coordination force to quantum dots, the disclosure is not limited thereto.

On the other hand, when a ligand including halogen atoms, for example, a ligand composed of fluorine which is a ligand composed of halogen atoms is used in the present embodiment as illustrated in (a) of FIG. 3, an aggregate QDA of the quantum dots QD is easily generated due to the short length of the ligand.

The distance between the quantum dots QD in the aggregate QDA of the quantum dots QD is shorter than the distance between the quantum dots QD other than the aggregate QDA of the quantum dots QD. For example, while the distance between the quantum dots QD in the aggregate QDA of quantum dots QD is 1 nm or less, the distance between the quantum dots QD other than the aggregate QDA of quantum dots QD is longer than 1 nm.

Although a shape of the aggregate QDA of the quantum dots QD is often spherical, the disclosure is not limited thereto. Note that, when the aggregate QDA of the quantum dots QD has a spherical shape, d that satisfies S=π(d/2)² with respect to the cross-sectional area S of the aggregate QDA of the quantum dots QD can be regarded as the diameter of the aggregate QDA.

Since the green light-emitting layer provided in the green light-emitting element 5G provided in the first region R1 of the display region DA of the display device 1 according to the first embodiment includes the quantum dots emitting green light and the ligand composed of fluorine, aggregates of quantum dots are likely to occur as in the red light-emitting layer 24REM provided in the red light-emitting element 5R illustrated in (a) of FIG. 3.

Since the blue light-emitting layer provided in the blue light-emitting element 5B provided in the first region R1 of the display region DA of the display device 1 according to the first embodiment includes the quantum dots emitting blue light and the ligand composed of fluorine, aggregates of quantum dots are likely to occur as in the red light-emitting layer 24REM provided in the red light-emitting element 5R illustrated in (a) of FIG. 3.

Although each of the red light-emitting element 5R, the green light-emitting element 5G, and the blue light-emitting element 5B provided in the first region R1 of the display region DA of the display device 1 according to the first embodiment can realize high luminous efficiency because the quantum dots are strongly protected by the ligand as described above, on the other hand, aggregates QDA of quantum dots QD are likely to occur, and the light-emitting elements easily break at sites where stress easily occurs.

Therefore, in the display device 1, the center portion of the display region DA where stress is less likely to occur is set as the first region R1, and each of the red light-emitting element 5R, the green light-emitting element 5G, and the blue light-emitting element 5B is provided in the first region R1, thereby improving the luminous efficiency of the light-emitting elements and preventing damage to the light-emitting elements.

The red light-emitting element 5R′ illustrated in (b) FIG. 3 is provided on the thin film transistor layer 4 including the transistor TR illustrated in FIG. 2, and includes the first electrode 22 as an anode, the second electrode 25 as a cathode, and a function layer including a red light-emitting layer provided between the first electrode 22 and the second electrode 25. The function layer including the red light-emitting layer is configured by layering a hole transport layer 24HT, a red light-emitting layer 24REM′, and an electron transport layer 24ET in order from the first electrode 22 side.

The red light-emitting layer 24REM′ includes an organic ligand and quantum dots. The quantum dots QD′ illustrated in (b) FIG. 3 means quantum dots to which the organic ligand is coordinated. Examples of the organic ligand include, but are not limited to, organic ligands composed of organic molecules having a certain length in order to prevent quantum dots from aggregating with each other. Examples of the organic ligand that can be used include, but are not limited to, oleylamine, oleic acid, dodecanethiol, trioctylphosphine, trioctylphosphine oxide, tributylphosphine oxide, and oleyl alcohol.

As illustrated in (b) of FIG. 3, when the red light-emitting layer 24REM′ includes an organic ligand, the aggregation of the quantum dots can be prevented, and the aggregate QDA of the quantum dots QD as illustrated in (a) of FIG. 3 is less likely to occur.

Since the green light-emitting layer provided in the green light-emitting element provided in the second region R2 of the display region DA of the display device 1 according to the first embodiment includes quantum dots emitting green light and an organic ligand, aggregates of quantum dots are less likely to occur as in the red light-emitting layer 24REM′ provided in the red light-emitting element 5R′ illustrated in (b) of FIG. 3.

Since the blue light-emitting layer provided in the blue light-emitting element provided in the second region R2 of the display region DA of the display device 1 according to the first embodiment includes quantum dots emitting blue light and an organic ligand, aggregates of quantum dots are less likely to occur as in the red light-emitting layer 24REM′ provided in the red light-emitting element 5R′ illustrated in (b) of FIG. 3.

Since each of the red light-emitting element 5R′, the green light-emitting element, and the blue light-emitting element provided in the second region R2 of the display region DA of the display device 1 according to the first embodiment includes the organic ligand, the protection of the quantum dots by the ligand is weak, and a decrease in the luminous efficiency of the light-emitting elements is unavoidable to some extent; however, on the other hand, occurrence of aggregates of quantum dots can be prevented, and thus, even if stress occurs, breakage of the light-emitting elements can be avoided.

Therefore, in the display device 1, regions including the end portions of the display region DA where stress is likely to occur are set as the second region R2, and each of the red light-emitting element 5R′, the green light-emitting element, and the blue light-emitting element provided with the light-emitting layers including quantum dots and organic ligands is provided in the second region R2, thereby preventing damage to the light-emitting elements.

A concentration of the aggregates QDA of the quantum dots QD which are the nanoparticle aggregates included in the red light-emitting layer 24REM illustrated in (a) of FIG. 3 is higher than a concentration of the aggregates of the quantum dots QD′ which are the nanoparticle aggregates included in the red light-emitting layer 24REM′ illustrated in (b) of FIG. 3.

Although each of the red light-emitting element 5R, the green light-emitting element 5G, and the blue light-emitting element 5B provided in the first region R1 of the display region DA of the display device 1 includes a light-emitting layer including a ligand composed of fluorine, each of the red light-emitting element 5R′, the green light-emitting element, and the blue light-emitting element provided in the second region R2 of the display region DA of the display device 1 includes a light-emitting layer including an organic ligand to set a concentration of halogen atoms included in the nanoparticle layers provided in the light-emitting elements (first light-emitting elements) provided in the first region R1 to be higher than a concentration of halogen atoms included in the nanoparticle layers provided in the light-emitting elements (second light-emitting elements) provided in the second region R2 in the present embodiment, the disclosure is not limited thereto. For example, each of the red light-emitting element 5R, the green light-emitting element 5G, and the blue light-emitting element 5B provided in the first region R1 of the display region DA of the display device 1 may include a light-emitting layer including both a ligand composed of fluorine and an organic ligand, each of the red light-emitting element 5R′, the green light-emitting element, and the blue light-emitting element provided in the second region R2 of the display region DA of the display device 1 may include a light-emitting layer including both a ligand composed of fluorine and an organic ligand, a concentration of halogen atoms in the light-emitting layer provided in each of the red light-emitting element 5R, the green light-emitting element 5G, and the blue light-emitting element 5B provided in the first region R1 of the display region DA of the display device 1 may be higher than a concentration of halogen atoms in the light-emitting layer provided in each of the red light-emitting element 5R′, the green light-emitting element, and the blue light-emitting element provided in the second region R2 of the display region DA of the display device 1.

Note that a concentration of halogen atoms means the number of halogen atoms included per certain volume, and can be calculated from, for example, SEM-EDX measurement results of a cross section of a light-emitting layer.

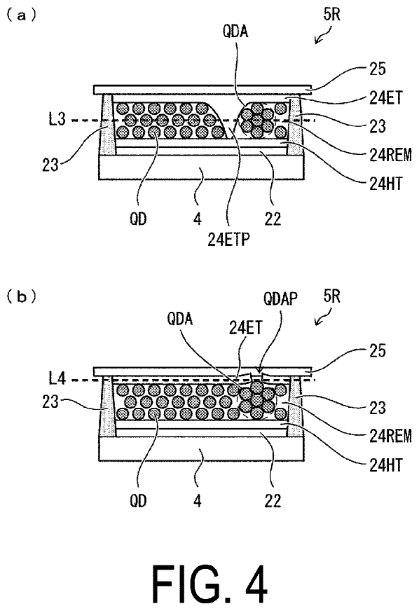

(a) and (b) of FIG. 4 are views illustrating an example of a phenomenon that may occur around the aggregate QDA of quantum dots QD of the red light-emitting element 5R provided in the first region R1 in the display region DA of the display device 1 according to the first embodiment.

As illustrated in (a) of FIG. 4, in the red light-emitting layer 24REM of the red light-emitting element 5R provided in the first region R1 in the display region DA of the display device 1, an aggregate QDA of the quantum dots QD is likely to occur as described above. In such a case, an electron transport layer 24ET provided directly above the red light-emitting layer 24REM, that is, an electron transport layer 24ET provided as an upper layer in contact with the red light-emitting layer 24REM and directly above the red light-emitting layer 24REM may be formed to have a protrusion 24ETP of the electron transport layer 24ET intruding into the red light-emitting layer 24REM serving as a lower layer. When the central position in the thickness of the maximum film thickness portion of the red light-emitting layer 24REM is set as a reference position L3 illustrated in (a) of FIG. 4, the number of portions of the electron transport layer 24ET provided directly above the red light-emitting layer 24REM, i.e., the electron transport layers 24ET provided in contact with the red light-emitting layer 24REM and as a layer directly above the red light-emitting layer 24REM, intruding into the reference position L3 of the red light-emitting layer 24REM serving as a lower layer or below is 1 per unit length of the red light-emitting layer 24REM.

The unit length of the red light-emitting layer 24REM means the lateral width of a cross-sectional view of the red light-emitting element 5R taken with a scanning electron microscope (SEM) at a magnification at which the number of intruding portions described above can be easily observed, and may be appropriately set in the range of, for example, 600 nm to 1000 nm.

The “thickness of the maximum film thickness portion of the red light-emitting layer 24REM” refers to the maximum film thickness portion in the thickness of the red light-emitting layer 24REM in a direction orthogonal to the unit length of the red light-emitting layer 24REM in a cross-sectional view of the red light-emitting element 5R taken with a scanning electron microscope (SEM) at a magnification at which the number of intruding portions described above can be easily observed. Note that, when the red light-emitting layer 24REM is observed to have a substantially uniform thickness in a cross-sectional view of the red light-emitting element 5R taken with a scanning electron microscope (SEM) at a magnification at which the number of intruding portions described above can be easily observed, the substantially uniform thickness of the red light-emitting layer 24REM can be regarded as a thickness of the maximum film thickness portion of the red light-emitting layer 24REM. Note that, the central position in the thickness of the maximum film thickness portion refers to a position at which the maximum film thickness portion is divided into two portions having a thickness that is half the thickness of the maximum film thickness portion.

The state of the electron transport layer 24ET intruding the reference position L3 of the red light-emitting layer 24REM or below refers to a state of the protrusion 24ETP of the electron transport layer 24ET being formed up to a region between the reference position L3 of the red light-emitting layer 24REM and the hole transport layer 24HT.

As illustrated in (b) of FIG. 3, in the red light-emitting layer 24REM′ of the red light-emitting element 5R′ provided in the second region R2 in the display region DA of the display device 1, no aggregate of the quantum dots QD′ is formed. In such a case, when the central position in the thickness of the maximum film thickness portion of the red light-emitting layer 24REM′ is set as a reference position L1 illustrated in (b) of FIG. 3, the number of portions of the electron transport layer 24ET provided directly above the red light-emitting layer 24REM′, i.e., the electron transport layer 24ET provided in contact with the red light-emitting layer 24REM′ and as a layer directly above the red light-emitting layer 24REM′, intruding into the reference position L1 of the red light-emitting layer 24REM′ serving as a lower layer or below is 0 per unit length of the red light-emitting layer 24REM′, which is smaller than 1 that is the number of portions of the electron transport layer 24ET described above intruding into the reference position L3 of the red light-emitting layer 24REM or below.

The unit length of the red light-emitting layer 24REM′ is preferably set to be the same as the unit length of the above-described red light-emitting layer 24REM.

The thickness of maximum film thickness portion of the red light-emitting layer 24REM′ refers to a maximum film thickness portion in the thickness of the red light-emitting layer 24REM′ in a direction orthogonal to the unit length of the red light-emitting layer 24REM′ in a cross-sectional view of a cross-section of the red light-emitting element 5R′ taken with a scanning electron microscope (SEM) by setting the unit length of the red light-emitting layer 24REM′ to be equal to the unit length of the red light-emitting layer 24REM. Note that, when the red light-emitting layer 24REM′ is observed to have a substantially uniform thickness in a cross-sectional view of the red light-emitting element 5R′ taken with a scanning electron microscope (SEM) by setting the unit length of the red light-emitting layer 24REM′ to be equal to the unit length of the red light-emitting layer 24REM, the substantially uniform thickness of the red light-emitting layer 24REM′ can be regarded as the thickness of the maximum film thickness portion of the red light-emitting layer 24REM′.

The state of the electron transport layer 24ET intruding into the reference position L1 of the red light-emitting layer 24REM′ or below refers to a state of the protrusion 24ETP of the electron transport layer 24ET being formed up to a region between the reference position L1 of the red light-emitting layer 24REM′ and the hole transport layer 24HT.

As illustrated in (b) of FIG. 4, in the red light-emitting layer 24REM of the red light-emitting element 5R provided in the first region R1 in the display region DA of the display device 1, an aggregate QDA of the quantum dots QD is likely to occur as described above. In such a case, the aggregate QDA of the quantum dots QD included in the red light-emitting layer 24REM may be formed such that a protrusion QDAP of the aggregate QDA of the quantum dots QD penetrates the electron transport layer 24ET provided directly above the red light-emitting layer 24REM, that is, the electron transport layer 24ET provided in contact with the red light-emitting layer 24REM and as an upper layer directly above the red light-emitting layer 24REM. When the central position in the thickness of the maximum film thickness portion of the electron transport layer 24ET is set as a reference position L4 illustrated in (b) of FIG. 4, the number of portions of the red light-emitting layer 24REM intruding the reference position L4 of the electron transport layer 24ET or further is 1 per unit length of the red light-emitting layer 24REM.

The “thickness of the maximum film thickness portion of the electron transport layer 24ET” refers to the maximum film thickness portion in the thickness of the electron transport layer 24ET in a direction orthogonal to the unit length of the red light-emitting layer 24REM in a cross-sectional view of the red light-emitting element 5R taken with a scanning electron microscope (SEM) at a magnification at which the number of intruding portions described above can be easily observed. Note that, when the electron transport layer 24ET is observed to have a substantially uniform thickness in a cross-sectional view of the red light-emitting element 5R taken with a scanning electron microscope (SEM) at a magnification at which the number of intruding portions described above can be easily observed, the substantially uniform thickness of the electron transport layer 24ET can be regarded as a thickness of the maximum film thickness portion of the electron transport layer 24ET.

The fact that the red light-emitting layer 24REM intruding into the reference position L4 of the electron transport layer 24ET or further means that the protrusion QDAP of the aggregate QDA of the quantum dots QD is formed to extend to the region between the reference position L4 of the electron transport layer 24ET and the second electrode 25.

As illustrated in (b) of FIG. 3, in the red light-emitting layer 24REM′ of the red light-emitting element 5R′ provided in the second region R2 in the display region DA of the display device 1, no aggregate of the quantum dots QD′ is formed. In such a case, when the central position in the thickness of the maximum film thickness portion of the electron transport layer 24ET is set as a reference position L2 illustrated in (b) of FIG. 3, the number of portions of the red light-emitting layer 24REM′ intruding into the reference position L2 of the electron transport layer 24ET or further, provided directly above the red light-emitting layer 24REM′, i.e., the electron transport layer 24ET provided in contact with the red light-emitting layer 24REM′ and as a layer directly above the red light-emitting layer 24REM′ is 0 per unit length of the red light-emitting layer 24REM′, which is smaller than 1 that is the number of portions of the red light-emitting layer 24REM described above intruding into the reference position L4 of the electron transport layer 24ET or further.

The unit length of the red light-emitting layer 24REM′ is preferably set to be the same as the unit length of the above-described red light-emitting layer 24REM.

The thickness of maximum film thickness portion of the electron transport layer 24ET refers to a maximum film thickness portion in the thickness of the electron transport layer 24ET in a direction orthogonal to the unit length of the red light-emitting layer 24REM′ in a cross-sectional view of the red light-emitting element 5R′ taken with a scanning electron microscope (SEM) by setting the unit length of the red light-emitting layer 24REM′ to be equal to the unit length of the red light-emitting layer 24REM. Note that, when the electron transport layer 24ET is observed to have a substantially uniform thickness in a cross-sectional view of the red light-emitting element 5R′ taken with a scanning electron microscope (SEM) by setting the unit length of the red light-emitting layer 24REM′ to be equal to the unit length of the red light-emitting layer 24REM, the substantially uniform thickness of the electron transport layer 24ET can be regarded as the thickness of the maximum film thickness portion of the electron transport layer 24ET.

The fact that the red light-emitting layer 24REM′ intruding into the reference position L2 of the electron transport layer 24ET or further means that the protrusion QDAP of the aggregate QDA of the quantum dots QD is formed to extend to the region between the reference position L2 of the electron transport layer 24ET and the second electrode 25.

Although the case in which the concentration of the halogen atoms included in the first layer which is the nanoparticle layer of the first light-emitting element provided in the first region R1 of the display region DA of the display device 1 is higher than the concentration of the halogen atoms included in the second layer which is the nanoparticle layer of the second light-emitting element provided in the second region R2 of the display region DA of the display device 1, the first light-emitting element and the second light-emitting element are in the conventional structure, and thus, the first layer and the second layer are light-emitting layers including quantum dots, and a third layer formed directly above the first layer and a fourth layer formed directly above the second layer are electron transport layers is exemplified as described above in the present embodiment, the disclosure is not limited thereto, and the third layer formed directly above the first layer and the fourth layer formed directly above the second layer may be electron injection layers. In addition, when the first light-emitting element and the second light-emitting element have the inverted-layered structure, the third layer formed directly above the first layer and the fourth layer formed directly above the second layer may be hole transport layers or hole injection layers.

When the first light-emitting element and the second light-emitting element have the conventional structure, the first layer and the second layer may be hole transport layers, and the third layer formed directly above the first layer and the fourth layer formed directly above the second layer may be light-emitting layers. In addition, when the first light-emitting element and the second light-emitting element have the inverted-layered structure, the first layer and the second layer may be hole transport layers, and the third layer formed directly above the first layer and the fourth layer formed directly above the second layer may be hole injection layers or either first electrodes or second electrodes that are electrode layers.

When the first light-emitting element and the second light-emitting element have the conventional structure, the first layer and the second layer may be electron transport layers, and the third layer formed directly above the first layer and the fourth layer formed directly above the second layer may be electron injection layers or either first electrodes or second electrodes that are electrode layers. In addition, when the first light-emitting element and the second light-emitting element have the inverted-layered structure, the first layer and the second layer may be electron transport layers, and the third layer formed directly above the first layer and the fourth layer formed directly above the second layer may be light-emitting layers.

When the first light-emitting element and the second light-emitting element have the inverted-layered structure, the first layer and the second layer may be hole injection layers, and the third layer formed directly above the first layer and the fourth layer formed directly above the second layer may be either first electrodes or second electrodes that are electrode layers.

When the first light-emitting element and the second light-emitting element have the conventional structure, the first layer and the second layer may be electron injection layers, and the third layer formed directly above the first layer and the fourth layer formed directly above the second layer may be either first electrodes or second electrodes that are electrode layers.

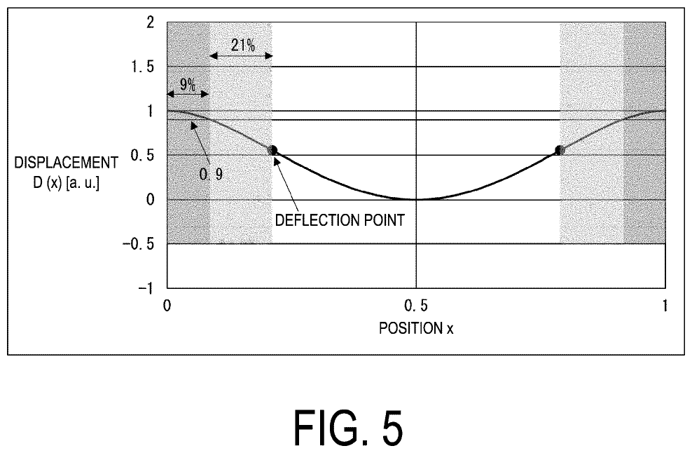

FIG. 5 is a graph for describing deflection due to the weight of the substrate 12 provided in the display device 1 according to the first embodiment.

As shown in FIG. 5, a deflection 8(x) of the substrate 12 at a position x due to a uniform load (assuming the weight of the substrate itself) when both ends of the substrate 12 having a length L are held is given as the following expression.

$$δ ( x ) = \frac{{qL}^{4}}{24 EI} {( x / L )}^{2} {( 1 - x / L )}^{2} \qquad [ Equation 1 ]$$

Wherein q is a load per unit length applied to the substrate 12 (proportional to the substrate density), E is the Young's modulus of the substrate 12, and I is the moment of inertia of the substrate 12. When it is assumed that L=1 and the positions of both ends of the substrate 12 are x=0 and 1, the following expression is obtained.

$$δ ( x ) ∝ {{x}^{2} ( 1 - x )}^{2} \qquad [ Equation 2 ]$$

FIG. 5 shows a displacement D(x) of the substrate 12 when the displacement D(x) at the center x=0.5 of the substrate 12 is set to 0 and the displacement D(x) at both ends x=0 and 1 of the substrate 12 is set to 1, and the displacement D(x) of the substrate 12 is expressed as the following expression. Wherein 1 in the first term and 0.54 in the second term are normalization constants.

$$D ( x ) = 1 - {{x}^{2} ( 1 - x )}^{2} / {0.5}^{4} \qquad [ Equation 3 ]$$

As the displacement D(x) is greater, the stress becomes greater and element destruction occurs more easily. A region (x=0 to 0.09, x=0.91 to 1) with the displacement D(x)>0.9 particularly has a large displacement D(x) and is prone to element destruction, and thus, the region is preferably the second region R2 of the display region DA described above.

In addition, x=0.21 and x=0.79 satisfying D″ (x)=0 are inflection points, and a region (x=0 to 0.21, x=0.79 to 1) outside these points is easily affected by deflection of the substrate 12, and thus is more preferably the second region R2 of the display region DA described above.

The second region R2 of the display region DA illustrated in FIG. 1 is preferably provided in at least one of a region (third region) formed in a width greater than 0% and 9% or less of the length of the substrate 12 in a first direction D1 from each of the two end portions D2ER and D2EL of the substrate 12 formed in a second direction D2, or a region (fourth region) formed in a width greater than 0% and 9% or less of the length of the substrate 12 in the second direction D2 from each of the two end portions D1EU and D1ED of the substrate 12 formed in the first direction D1.

In addition, the second region R2 of the display region DA illustrated in FIG. 1 is more preferably provided in at least one of a region (third region) formed in a width greater than 9% and 21% or less of the length of the substrate 12 in the first direction D1 from each of the two end portions D2ER and D2EL of the substrate 12 formed in the second direction D2, or a region (fourth region) formed in a width greater than 9% and 21% or less of the length of the substrate 12 in the second direction D2 from each of the two end portions D1EU and D1ED of the substrate 12 formed in the first direction D1.

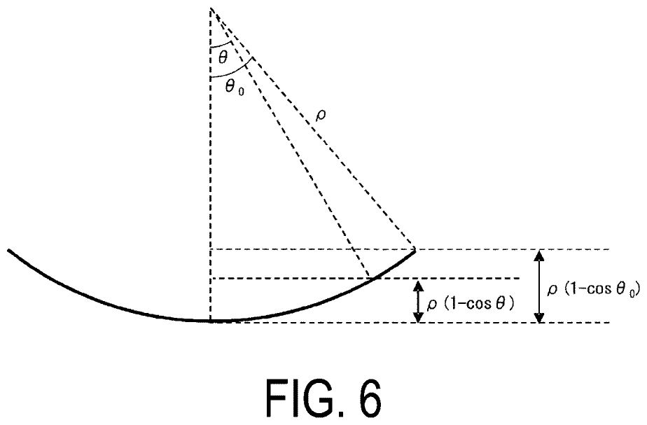

FIG. 6 is a diagram for describing a site where stress is likely to occur in a case that there are the substrate 12 included in the display device 1 of the first embodiment and a layer having a thermal expansion coefficient different from that of the substrate 12 that is provided on the substrate 12.

Since the substrate 12 and each layer provided on the substrate 12 generally have different thermal expansion coefficients, stress is generated when the substrate 12 is heated. For example, when a first thin plate having a thickness h₁, a Young's modulus E₁, and a thermal expansion coefficient α₁ and a second thin plate having a thickness h₂, a Young's modulus E₂, and a thermal expansion coefficient α₂ are in contact with the substrate 12, a curvature radius ρ of deformation caused by a temperature rise ΔT is given as the following expression. However, h=h₁+h₂, m=E₁/E₂, and n=h₁/h₂.

$$\frac{1}{ρ} = \frac{6 ( {α}_{2} − {α}_{1} ) Δ {T ( 1 + n )}^{2}}{h [ 3 {( 1 + n )}^{2} + ( 1 + mn ) ( {n}^{2} + \frac{1}{m n} ) ]} \qquad [ Equation 4 ]$$

For the deformation of the substrate 12 caused by heating, θ is determined as shown in FIG. 6, and θ=θ₀ is set for the ends of the substrate 12. That is, the length L of the substrate 12 is set as L=2ρθ₀. Since the thickness (several hundreds nm) of each layer provided on the substrate 12 is extremely thin when compared to the thickness (several mm) of the substrate 12, the curvature radius ρ can be approximated to be large and θ to be small compared to the length L of the substrate 12. For displacement p of the entire substrate 12 (1−cos θ₀), θ at which displacement is 90% is given in the following expression.

$$ρ ( 1 - cos θ ) = 0.9 \times ρ ( 1 - cos {θ}_{0} ) \qquad [ Equation 5 ]$$

If the approximation 1−cos θ≅½×θ² when θ is small is used, θ/θ₀=0.95 can be obtained as shown below.

$${θ}^{2} = 0.9 \times {θ}_{0}^{2} \qquad [ Equation 6 ]$$

$$θ / {θ}_{0} = \sqrt{0.9} = 0.95 \qquad [ Equation 7 ]$$

The outer side of θ (5%=100%−95% of the end portion of a half of the substrate 12), that is, the range of 3% of the end portion of the substrate 12 is extremely susceptible to stress caused by thermal expansion, and thus is preferably set as the second region R2 of the display region DA described above.

Similarly, for θ at which the displacement is 50%, θ/θ₀=0.71 can be obtained as shown below.

$$θ / {θ}_{0} = \sqrt{0.5} = 0.71 \qquad [ Equation 8 ]$$

The outer side of θ (29%=100%−71% of the end portion of a half of the substrate 12), that is, the range of 15% of the end portion of the substrate 12 is susceptible to stress caused by thermal expansion, and thus is more preferably set as the second region R2 of the display region DA described above.

The second region R2 of the display region DA illustrated in FIG. 1 is preferably provided in at least one of a region (third region) formed in a width greater than 0% and 3% or less of the length of the substrate 12 in the first direction D1 from each of the two end portions D2ER and D2EL of the substrate 12 formed in the second direction D2, or a region (fourth region) formed in a width greater than 0% and 3% or less of the length of the substrate 12 in the second direction D2 from each of the two end portions D1EU and D1ED of the substrate 12 formed in the first direction D1.

In addition, the second region R2 of the display region DA illustrated in FIG. 1 is more preferably provided in at least one of a region (third region) formed in a width greater than 3% and 15% or less of the length of the substrate 12 in the first direction D1 from each of the two end portions D2ER and D2EL of the substrate 12 formed in the second direction D2, or a region (fourth region) formed in a width greater than 3% and 15% or less of the length of the substrate 12 in the second direction D2 from each of the two end portions D1EU and D1ED of the substrate 12 formed in the first direction D1.

Furthermore, the second region R2 of the display region DA illustrated in FIG. 1 is most preferably provided in at least one of a region (third region) formed in a width 3% or greater and 15% or less of the length of the substrate 12 in the first direction D1 from each of the two end portions D2ER and D2EL of the substrate 12 formed in the second direction D2, or a region (fourth region) formed in a width 3% or greater and 15% or less of the length of the substrate 12 in the second direction D2 from each of the two end portions D1EU and D1ED of the substrate 12 formed in the first direction D1.

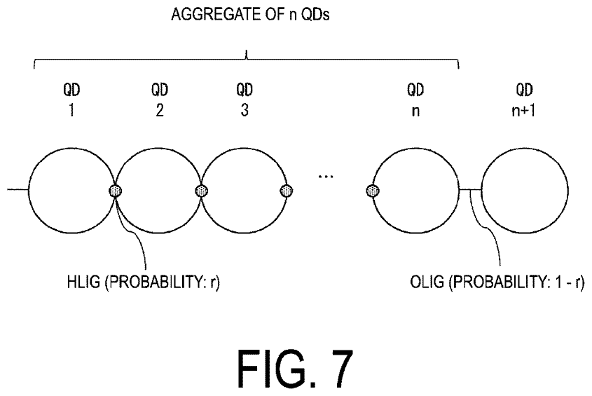

FIG. 7 is a diagram for describing the coverage proportion of a quantum dot with respect to a halogen ligand HLIG in a light-emitting layer included in a light-emitting element included in each subpixel of the display device 1 according to the first embodiment.

An area of the halogen ligand HLIG/a surface area of a quantum dot which indicates the coverage proportion of the quantum dot with respect to the halogen ligand HLIG is represented by r.

An organic ligand OLIG can be used to prevent aggregation of the quantum dots. As illustrated in FIG. 7, the organic ligand OLIG is present in a portion of 1−r where the halogen ligand HLIG is not present in the surface area of the quantum dot.

If a quantum dot dispersion solution is considered to be one dimensional for simplicity and the halogen ligand HLIG is present between two quantum dots (probability r), the distance between the two quantum dots becomes shorter and thus the quantum dots aggregate, and if an organic ligand OLIG is present (probability 1-r), the distance between the two quantum dots becomes longer and thus the quantum dots do not aggregate.

The probability P (n) at which n quantum dots aggregate is given as the following expression.

$$P ( n ) = {r}^{n - 1} ( 1 - r ) \qquad [ Equation 9 ]$$

The average number (expected value of n) E of quantum dots in the one dimensional aggregate of n quantum dots illustrated in FIG. 7 is given as the following expression.

$$E = {\sum }_{n = 1}^{∞} nP ( n ) = {\sum }_{n = 1}^{∞} {nr}^{n - 1} ( 1 - r ) = \frac{1}{1 - r} \qquad [ Equation 10 ]$$

If the thickness of the light-emitting layer including quantum dots is roughly the thickness of three stacked quantum dots since the luminous efficiency is high, in the second region R2 of the display region DA described above, the size of the aggregate of the quantum dots is smaller than the thickness of the light-emitting layer. That is, when E<3 and r<0.67, the size of the aggregate of the quantum dots becomes smaller than the thickness of the light-emitting layer, so element destruction caused by stress is unlikely to occur.

In the first region R1 of the display region DA described above, if the size of the aggregate of the quantum dots is less than the thickness of layered five quantum dots (E<5, that is, r<0.8), the light-emitting layer including the quantum dots can be formed to be substantially flat, and a problem of element characteristics is unlikely to occur.

From the above, it is preferable that the coverage proportion of a nanoparticle with respect to a halogen atom in the first region R1 of the display region DA be 67% or greater and 80% or less, and the coverage proportion of a nanoparticle with respect to a halogen atom in the second region R2 of the display region DA be 0% or greater and less than 67%.

Note that r which represents (area of halogen ligand HLIG/surface area of a quantum dot) can be obtained, for example, from the result of cross-sectional SEM-EDX (the number of halogens per unit volume N) as follows.

r which is represented by the expression r=the number of halogens per unit volume N×the volume of the quantum dot×the area occupied by one halogen atom/surface area of the quantum dot can be obtained as shown below. However, d_{Q} is the diameter of the quantum dot, dₕ is twice the ionic radius of the halide ion, and the ionic radius is 0.13 nm for F.

$$r = \frac{N \times \frac{4 π}{3} {( \frac{{d}_{Q}}{2} )}^{3} \times π {( \frac{{d}_{h}}{2} )}^{2}}{4 π {( \frac{{d}_{Q}}{2} )}^{3}} \qquad [ Equation 11 ]$$

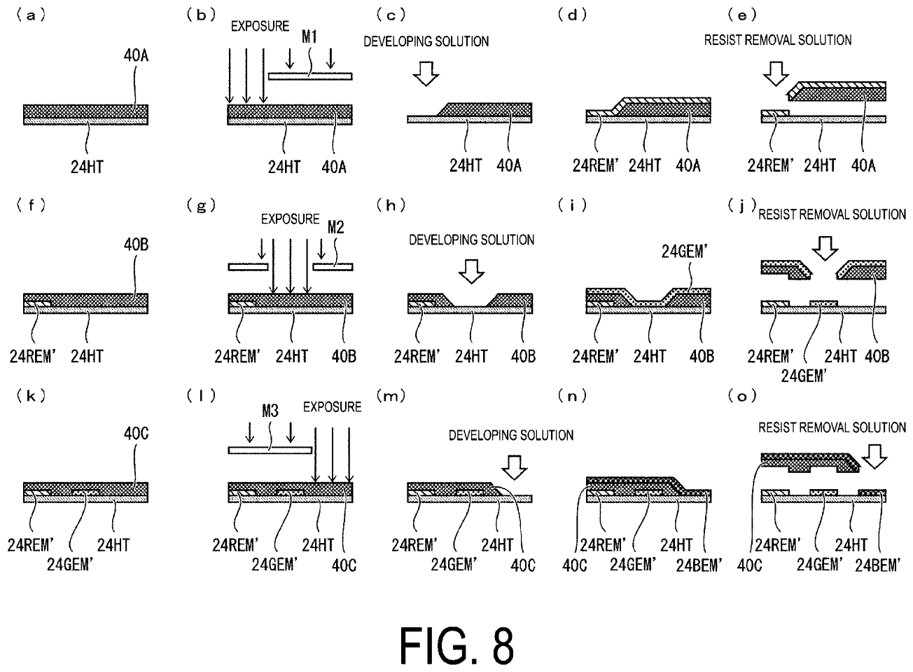

In the following, a red light-emitting layer forming process of forming the red light-emitting layer 24REM′, a green light-emitting layer forming process of forming the green light-emitting layer 24GEM′, and a blue light-emitting layer forming process of forming the blue light-emitting layer 24BEM′ will be described with reference to FIG. 8.

(a) to (o) of FIG. 8 are diagrams illustrating an example of a process of forming quantum dot layers, which is part of a process of forming the light-emitting layers included in the light-emitting elements included in the respective subpixels of the display device 1 according to the first embodiment, by using a lift-off method. Note that, in (a) to (o) of FIG. 8, the first electrodes 22 included in the light-emitting elements of the respective colors are not illustrated.

A patterning process for the red light-emitting layer 24REM′, the green light-emitting layer 24GEM′, and the blue light-emitting layer 24BEM′ using the lift-off method includes a process of forming a first photosensitive resin layer 40A on the hole transport layer 24HT illustrated in (a) of FIG. 8, a process of exposing the first photosensitive resin layer 40A using a mask M1 illustrated in (b) of FIG. 8, a process of development using a developing solution illustrated in (c) of FIG. 8 to form an opening in the first photosensitive resin layer 40A, a process of obtaining the red light-emitting layer 24REM′ by applying a solution including red light-emitting quantum dots illustrated in (d) of FIG. 8 and performing heat treatment, and a process of obtaining the patterned red light-emitting layer 24REM′ by removing the first photosensitive resin layer 40A using a resist removal solution illustrated in (e) of FIG. 8. The patterning process for the red light-emitting layer 24REM′, the green light-emitting layer 24GEM′, and the blue light-emitting layer 24BEM′ using the lift-off method further includes a process of forming a second photosensitive resin layer 40B on the red light-emitting layer 24REM′ and the hole transport layer 24HT illustrated in (f) of FIG. 8, a process of exposing the second photosensitive resin layer 40B using a mask M2 illustrated in (g) of FIG. 8, a process of development using a developing solution illustrated in (h) of FIG. 8 to form an opening in the second photosensitive resin layer 40B, a process of obtaining the green light-emitting layer 24GEM′ by applying a solution including green light-emitting quantum dots illustrated in (i) of FIG. 8 and performing heat treatment, and a process of obtaining the patterned green light-emitting layer 24GEM′ by removing the second photosensitive resin layer 40B using a resist removal solution illustrated in (j) of FIG. 8. The patterning process for the red light-emitting layer 24REM′, the green light-emitting layer 24GEM′, and the blue light-emitting layer 24BEM′ using the lift-off method further includes a process of forming a third photosensitive resin layer 40C on the red light-emitting layer 24REM′, the green light-emitting layer 24GEM′, and the hole transport layer 24HT illustrated in (k) of FIG. 8, a process of exposing the third photosensitive resin layer 40C using a mask M3 illustrated in (l) of FIG. 8, a process of development using a developing solution illustrated in (m) of FIG. 8 to form an opening in the third photosensitive resin layer 40C, a process of obtaining the blue light-emitting layer 24BEM′ by applying a solution including blue light-emitting quantum dots illustrated in (n) of FIG. 8 and performing heat treatment, and a process of obtaining the patterned blue light-emitting layer 24BEM′ by removing the third photosensitive resin layer 40C using a resist removal solution illustrated in (o) of FIG. 8. Note that, although PGMEA or the like can be used as the resist removal solutions illustrated in (e), (j), and (o) of FIG. 8, for example, examples of the resist removal solution are not limited thereto. In addition, although a case in which the red light-emitting layer 24REM′, the green light-emitting layer 24GEM′, and the blue light-emitting layer 24BEM′ are formed in this order is exemplified in the present embodiment, the disclosure is not limited thereto, and a light-emitting layer of any color may be formed first.

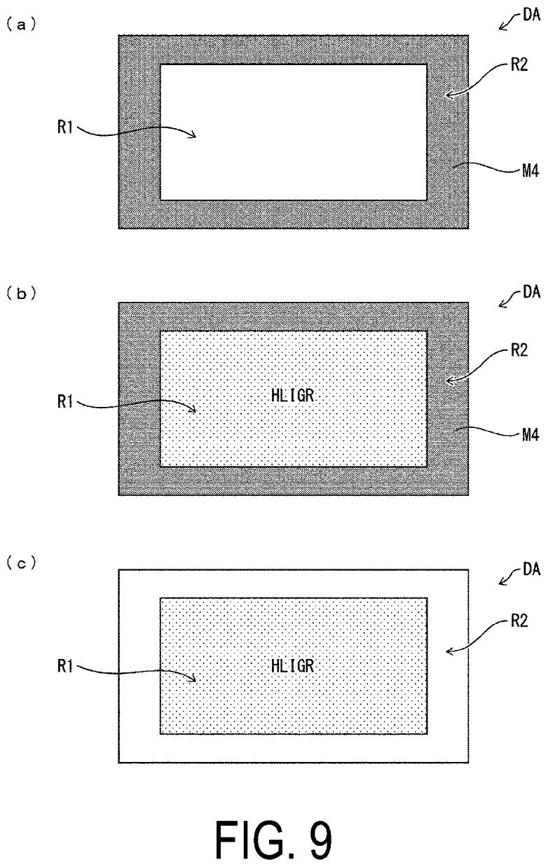

(a) to (c) of FIG. 9 are diagrams illustrating an example of a process of incorporating a halogen ligand HLIG into only the first region R1 in the display region DA of the display device 1 of the first embodiment.

As illustrated in (a) of FIG. 9, a mask M4 having an opening in a region corresponding to the first region R1 of the display region DA and serving as a light-shielding portion in a region corresponding to the second region R2 of the display region DA is disposed on the substrate on which the red light-emitting layer 24REM′, the green light-emitting layer 24GEM′, and the blue light-emitting layer 24BEM′ illustrated in (o) of FIG. 8 are formed.

Thereafter, a solution including a halogen ligand HLIG is applied with the mask M4 placed as illustrated in (b) of FIG. 9, and thereby a region HLIGR having a high concentration of the halogen ligand HLIG only can be formed in the first region R1, which is the central portion of the display region DA. Note that before applying the solution including the halogen ligand HLIG, at least a part of the organic ligand OLIG in the first region R1, which is the central portion of the display region DA, may be removed with an alcohol solution as necessary. Note that, as the alcohol solution, for example, methanol or ethanol can be suitably used, but examples of the alcohol solution are not limited thereto.

Then, as a result of removing the mask M4 as illustrated in (c) of FIG. 9, the concentration of halogen atoms included in each of the red light-emitting layer 24REM, the green light-emitting layer, and the blue light-emitting layer provided in the first region R1 can be higher than the concentration of halogen atoms included in each of the red light-emitting layer 24REM′, the green light-emitting layer 24GEM′, and the blue light-emitting layer 24BEM′ provided in the second region R2.

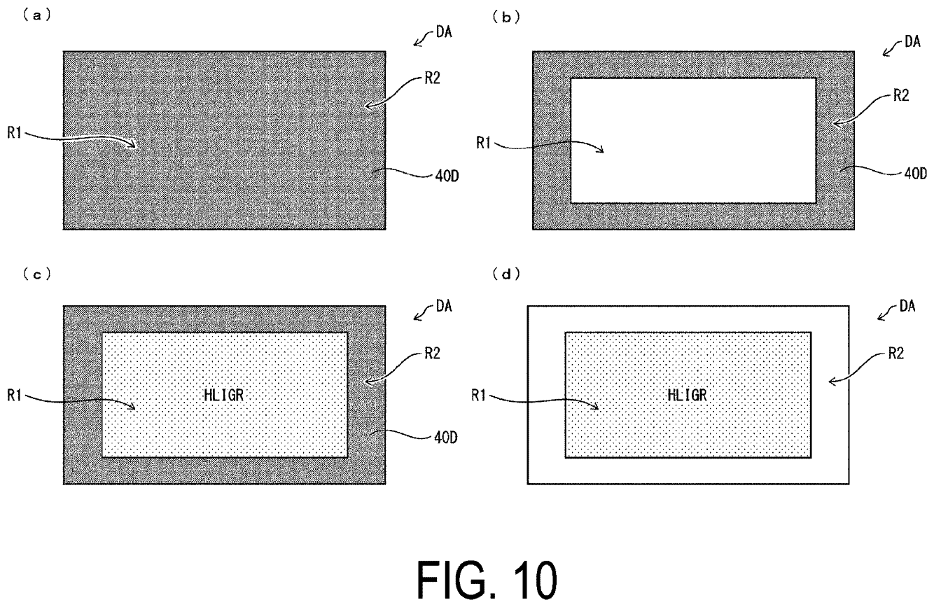

(a) to (d) of FIG. 10 are diagrams illustrating another example of the process of incorporating a halogen ligand HLIG into only the first region R1 in the display region DA of the display device 1 of the first embodiment.

As illustrated in (a) of FIG. 10, the fourth photosensitive resin layer 40D is formed on the entire surface of the substrate on which the red light-emitting layer 24REM′, the green light-emitting layer 24GEM′, and the blue light-emitting layer 24BEM′ illustrated in (o) of FIG. 8 are formed.

Thereafter, as illustrated in (b) of FIG. 10, the fourth photosensitive resin layer 40D is patterned by exposing it using a mask, which is not illustrated, and then developing it, so an opening can be formed in a region corresponding to the first region R1 of the display region DA.

Thereafter, as illustrated in (c) of FIG. 10, in a state in which the fourth photosensitive resin layer 40D having the opening in the region corresponding to the first region R1 of the display region DA is formed, a solution including the halogen ligand HLIG is applied, whereby a region HLIGR having a high concentration of the halogen ligand HLIG can be formed only in the first region R1 which is the central portion of the display region DA. Note that, before applying the solution including the halogen ligand HLIG, at least a part of the organic ligand OLIG in the first region R1, which is the central portion of the display region DA, may be removed with an alcohol solution as necessary. Note that as the alcohol solution, for example, methanol or ethanol can be suitably used, but examples of the alcohol solution are not limited thereto.

Then, as a result of removing the fourth photosensitive resin layer 40D as illustrated in (d) of FIG. 10, the concentration of halogen atoms included in each of the red light-emitting layer 24REM, the green light-emitting layer, and the blue light-emitting layer provided in the first region R1 can be higher than the concentration of halogen atoms included in each of the red light-emitting layer 24REM′, the green light-emitting layer 24GEM′, and the blue light-emitting layer 24BEM′ provided in the second region R2.

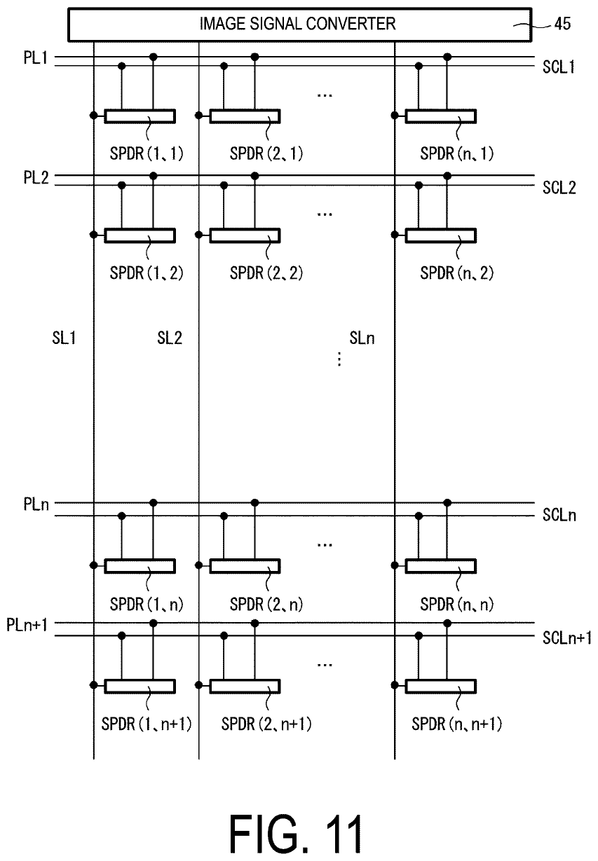

FIG. 11 is a diagram illustrating an image signal converter 45, subpixel circuits SPDR, and various wires provided in the display device 1 according to the first embodiment.

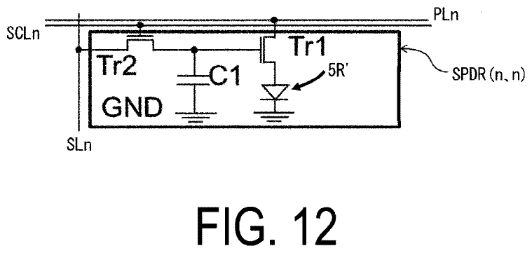

FIG. 12 is a diagram illustrating an example of a subpixel circuit SPDR provided in the display device 1 according to the first embodiment.

As illustrated in FIG. 12, the subpixel circuit SPDR (n, n) includes, for example, a transistor Tr1, a transistor Tr2, and a capacitor C1. The transistor Tr1 is a drive transistor configured to drive the red light-emitting element 5R′ (e.g., the transistor TR of the thin film transistor layer 4 illustrated in FIG. 2). The source electrode of the transistor Tr1 is connected to a power source line PLn to which a voltage of a first level (e.g., a high level) is applied, the gate electrode of the transistor Tr1 is connected to the drain electrode of the transistor Tr2 and one terminal of the capacitor C1, and the drain electrode of the transistor Tr1 is connected to the anode electrode of the red light-emitting element 5R′. The transistor Tr2 is a selection transistor for selecting a light-emitting element to be caused to emit light in accordance with a scanning signal supplied from a scanning line SCLn. The source electrode of the transistor Tr2 is connected to a signal line SLn, the gate electrode of the transistor Tr2 is connected to the scanning line SCLn, and the drain electrode of the transistor Tr2 is connected to the gate electrode of the transistor Tr1 and one terminal of the capacitor C1.

In the red light-emitting element 5R′, the cathode electrode opposite to the anode electrode connected to the transistor Tr1 and the other terminal of the capacitor C1 opposite to the one terminal are grounded by being connected to a GND line to which a voltage of a second level (e.g., a low level) is applied.

When a scanning signal is supplied from the scanning line SCLn to the transistor Tr2, the transistor Tr2 is turned on, and at the same time, the image signal converter 45 illustrated in FIG. 11 supplies a data signal to the signal lines SL1 to SLn, and the signal is transmitted to the transistor Tr1 via the transistor Tr2. As a result, a current corresponding to the data signal flows through the light-emitting element provided in each of the subpixel circuits SPDR (1, 1) to SPDR (n, n+1), and thereby the light-emitting element emits light.

As described above, in the display device 1, since the concentration of halogen atoms included in each of the red light-emitting layer 24REM, the green light-emitting layer, and the blue light-emitting layer provided in the first region R1 is higher than the concentration of halogen atoms included in each of the red light-emitting layer 24REM′, the green light-emitting layer 24GEM′, and the blue light-emitting layer 24BEM′ provided in the second region R2, the element characteristics of the first light-emitting element provided in the first region R1 are different from the element characteristics of the second light-emitting element provided in the second region R2.

Therefore, in the present embodiment, a characteristic test (measurement of the relationship between a current density J and a luminance L) of each subpixel is performed after completion of the manufacturing, and the result is stored in the image signal converter 45. For example, assuming that the luminance L is proportional to the current density J, L=AJ (A represents a coefficient/luminous efficiency), and the luminance L₀ when each subpixel is driven at a predetermined current density J₀ is measured to obtain a coefficient A (=L₀/J₀). The image signal converter 45 stores the coefficient A for each subpixel, and determines and output a data signal to have a current density J₁(=L₁/A) at which each subpixel emits light with a predetermined luminance L₁ based on the stored coefficient A when the subpixel is to be driven.

In the display device 1, since the luminous efficiency of the first light-emitting elements is higher than the luminous efficiency of the second light-emitting elements as described above in each of the first light-emitting elements provided in the first region R1 and the second light-emitting elements provided in the second region R2, the drive current corresponding to the same luminance is smaller in the first light-emitting elements than in the second light-emitting elements.

The display device 1 of the present embodiment includes the image signal converter 45 illustrated in FIG. 11. In addition, the image signal converter 45 stores a first coefficient (A=L1/J1) indicating a relationship between a predetermined current density J1 in the first light-emitting elements and a luminance L1 corresponding to the predetermined current density J1, and a second coefficient (B=L2/J2) indicating a relationship between a predetermined current density J2 in the second light-emitting elements and a luminance L2 corresponding to the predetermined current density J2. The image signal converter 45 converts a first data signal related to a drive current of the first light-emitting element based on the first coefficient and supplies the first data signal to the first light-emitting element, and converts a second data signal related to the drive current of the second light-emitting element based on the second coefficient and supplies the second data signal to the second light-emitting element.

Note that, a case in which the display region DA includes the first region R1 and the second region R2, and the second region R2 surrounds the first region R1 in a frame shape is exemplified in the present embodiment as illustrated in FIG. 1, the disclosure is not limited thereto. Although not illustrated, for example, the second region R2 surrounding the first region R1 in a frame shape may further include n (n is a natural number of 2 or greater) frame-shaped regions. For example, when n is 2 and the second region R2 surrounding the first region R1 in a frame shape includes two frame-shaped regions, the second region R2 may include a first frame-shaped second region closer to the first region R1 and a second frame-shaped second region farther from the first region R1, and the concentration of halogen atoms included in the nanoparticle layer included in the second light-emitting elements provided in the first second region may be higher than the concentration of halogen atoms included in the nanoparticle layer included in the second light-emitting elements provided in the second second region. With such a configuration, it is possible to improve the luminous efficiency of the second light-emitting elements provided in the first second region more than the luminous efficiency of the second light-emitting elements provided in the second second region while reducing the possibility of breakage of the second light-emitting elements.

### Second Embodiment

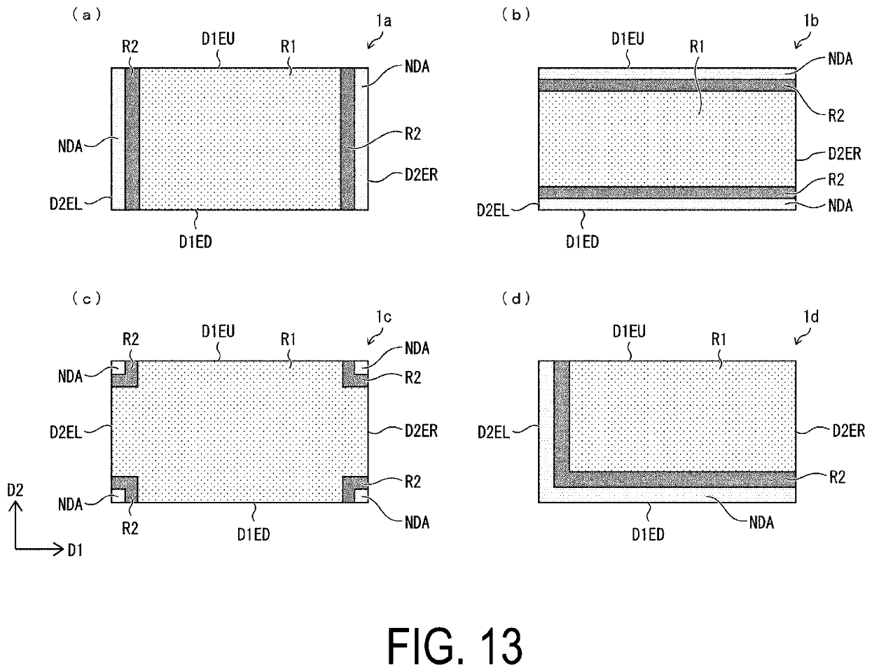

Next, a second embodiment of the disclosure will be described with reference to FIG. 13. Display devices 1a, 1b, 1c, and 1d according to the present embodiment are different from the display device 1 described in the first embodiment in that the shape of the first region R1 including at least a part of the central portion of the display region DA and the shape of the second region R2 including at least a part of the end portions of the display region DA are different. The other details are as described in the first embodiment. For convenience of description, members having the same functions as those shown in the drawings according to the first embodiment are denoted by the same reference numerals and signs, and descriptions thereof will be omitted.

(a) to (d) of FIG. 13 are plan views illustrating examples of the display devices 1a, 1b, 1c, and 1d according to the second embodiment.

As illustrated in (a) of FIG. 13, the display device 1a includes a substrate 12 having a length in a first direction D1 which is a longitudinal direction and a length in a second direction D2 which is orthogonal to a first direction D1, and including a display region DA and frame portions NDA. The frame portions NDA are provided in the second direction D2 closer to each of two end portions D2EL and D2ER of the substrate 12 formed in the second direction D2 than to the second regions R2. Note that, although a case in which the display device 1a includes the frame portions NDA is exemplified in the present embodiment, the disclosure is not limited thereto, and in the display device 1a, the frame portions NDA may not be provided, and the second regions R2 may be provided instead of the frame portions NDA.

According to the display device 1a, since the frame portions NDA are present only on the short sides of the display device 1a, the regions of the frame portions NDA can be reduced as compared with a case in which the frame portions NDA are provided on the long side of the display device 1a, so the display region DA having a larger size can be ensured.

In addition, when the frame portions NDA are not provided and the second regions R2 are provided instead of the frame portions NDA in the display device 1a, it is possible to secure the display region DA having a larger size.

As illustrated in (b) of FIG. 13, the display device 1b includes a substrate 12 having a length in the first direction D1 which is a longitudinal direction and a length in the second direction D2 which is orthogonal to the first direction D1 and including a display region DA and frame portions NDA. The frame portions NDA are provided in the first direction D1 closer to each of two end portions D1EU and D1ED of the substrate 12 formed in the first direction D1 than to the second regions R2. Although a case in which the display device 1b includes the frame portions NDA is exemplified in the present embodiment, the disclosure is not limited thereto, and in the display device 1b, the frame portions NDA may not be provided, and the second regions R2 may be provided instead of the frame portions NDA.

According to the display device 1b, by clamping the long sides of the display device 1b, it is possible to reduce stress caused by the weight of the display device even if it is a large-sized display.

In addition, when the frame portions NDA are not provided and the second regions R2 are provided instead of the frame portions NDA in the display device 1b, it is possible to secure the display region DA having a larger size.

As illustrated in (c) of FIG. 13, the display device 1c includes a substrate 12 having a length in the first direction D1 which is a longitudinal direction and a length in the second direction D2 which is orthogonal to the first direction D1 and including a display region DA and frame portions NDA. The frame portions NDA are provided at four corner portions where two end portions D1EU and D1ED of the substrate 12 formed in the first direction D1 and two end portions D2EL and D2ER of the substrate 12 formed in the second direction D2 are in contact with each other, and are provided closer to the corner portions than to the second regions R2. The disclosure is not limited to this configuration, and the frame portions NDA may be provided only at least at two corner portions that are most distant from each other among the four corner portions. Furthermore, although the case in which the display device 1c includes the frame portions NDA is exemplified in the present embodiment, the disclosure is not limited thereto, and in the display device 1c, the frame portions NDA may not be provided, and the second regions R2 may be provided at the four corner portions or only at two corner portions.

According to the display device 1c, since the frame portions NDA are provided at the four corner portions or only at the two corner portions, the region of the frame portions NDA can be reduced, and thus the display region DA having a larger size can be ensured.

In addition, in the display device 1c, when the frame portions NDA are not provided and the second regions R2 are provided at the four corner portions or only at two corner portions, it is possible to secure the display region DA having a larger size.

As illustrated in (d) of FIG. 13, the display device 1d includes a substrate 12 having a length in the first direction D1 which is a longitudinal direction and a length in the second direction D2 which is orthogonal to the first direction D1 and including a display region DA and a frame portion NDA. Although the case in which the frame portion NDA is provided at the end portions D1ED and D2EL of the substrate 12 in which the second region R2 is provided and is provided closer to the end portions D1ED and D2EL of the substrate 12 than to the second region R2 is exemplified in the present embodiment, the disclosure is not limited thereto. For example, the frame portion NDA may be formed to include a portion formed in the first direction D1 close to one of the two end portions D1EU and D1ED of the substrate 12 formed in the first direction D1 and a portion formed in the second direction D2 close to one of the two end portions D2EL and D2ER of the substrate 12 formed in the second direction D2.

In addition, although the case in which the display device 1d includes the frame portion NDA is exemplified in the present embodiment, the disclosure is not limited thereto, and the display device 1d may include no frame portions NDA. In the display device 1d including no frame portions NDA as described above, the second region R2 may be formed to include the portion formed in the first direction D1 close to one of the two end portions D1EU and D1ED of the substrate 12 formed in the first direction D1 and the portion formed in the second direction D2 close to one of the two end portions D2EL and D2ER of the substrate 12 formed in the second direction D2.

According to the display device 1d, since the frame portion NDA is provided on two sides including one corner, the region of the frame portion NDA can be reduced, and thus the display region DA having a larger size can be ensured.

In addition, in the display device 1d, if the frame portion NDA is not provided and the second region R2 is provided on two sides including one corner, the display region DA having a larger size can be ensured.

In addition, in the display device according to the present embodiment, regardless of the arrangement position of the second region R2, the frame portions NDA may be provided in any one of (1) the first frame regions in the second direction D2 including the two end portions D2EL and D2ER of the substrate 12 formed in the second direction D2, (2) the second frame regions in the first direction D1 including the two end portions D1EU and D1ED of the substrate 12 formed in the first direction D1, (3) the third frame regions that are two corner portions that are at least most distant from each other among the four corner portions at which the two end portions D1EU and D1ED of the substrate 12 formed in the first direction D1 are in contact with the two end portions D2EL and D2ER of the substrate 12 formed in the second direction D2, and (4) the fourth frame region including the portion formed in the first direction D1 to include one of the two end portions D1EU and D1ED of the substrate 12 formed in the first direction D1 and the portion formed in the second direction D2 to include one of the two end portions D2EL and D2ER of the substrate 12 formed in the second direction D2.

### Third Embodiment

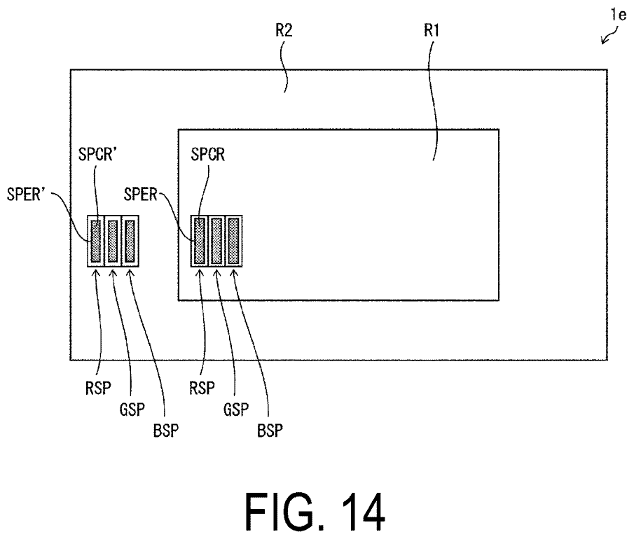

Next, a third embodiment of the disclosure will be described with reference to FIG. 14. The display device 1e of the present embodiment differs from the display devices described in the first and second embodiments in that first light-emitting elements provided in a first region R1 are included in first subpixels, second light-emitting elements provided in the second region R2 are included in second subpixels, a light-emitting layer which is a nanoparticle layer including nanoparticles of the first subpixels and a light-emitting layer which is a nanoparticle layer including nanoparticles of the second subpixels each include inner regions SPCR and SPCR′ and outer regions SPER and SPER′, the inner regions SPCR and SPCR′ have a higher concentration of halogen atoms than that of the outer regions SPER and SPER′, a ratio of the area of the inner regions SPCR and SPCR′ to the area of a subpixel is higher in the first subpixels than in the second subpixels. The other details are as described in the first and second embodiments. For convenience of description, members having the same functions as those shown in the drawings according to the first and second embodiments are denoted by the same reference numerals and signs, and descriptions thereof will be omitted.

FIG. 14 is a plan view illustrating an example of a display device 1e according to the third embodiment.

As illustrated in FIG. 14, in the display device 1e, the first light-emitting elements provided in the first region R1 are included in the first subpixels, the second light-emitting elements provided in the second region R2 are included in the second subpixels, the light-emitting layer which is a nanoparticle layer including nanoparticles of the first subpixels and the light-emitting layer which is a nanoparticle layer including nanoparticles of the second subpixels each include the inner regions SPCR and SPCR′ and the outer regions SPER and SPER′, the inner regions SPCR and SPCR′ have a higher concentration of halogen atoms than that of the outer regions SPER and SPER′, and a ratio of the area of the inner regions SPCR and SPCR′ to the area of a subpixel is higher in the first subpixels than in the second subpixels. By setting the concentration of halogen atoms in the outer regions SPER and SPER′ to be lower than that in the inner regions SPCR and SPCR′, the luminous efficiency in the outer regions SPER and SPER′ will be lowered than that of the inner regions SPCR and SPCR′; however the light emission in the outer regions SPER and SPER′ caused by a leakage current from adjacent subpixels may be suppressed.

Thus, in the display device 1e, the concentration of halogen atoms included in the nanoparticle layer provided in one or more light-emitting elements (first light-emitting elements) of the red light-emitting element, green light-emitting element, and blue light-emitting element provided in the first region R1 becomes higher than the concentration of halogen atoms included in the nanoparticle layer provided in one or more light-emitting elements (second light-emitting elements) of the red light-emitting element, green light-emitting element, and blue light-emitting element provided in the second region R2.

In addition, in the display device 1e, two or more second subpixels each including the second light-emitting element may be provided in the second region R2, and the concentration of halogen atoms included in the nanoparticle layer of the second subpixel disposed closer to the first region R1 among the two or more second subpixels may be higher than the concentration of halogen atoms included in the nanoparticle layer of the second subpixel disposed farther from the first region R1 among the two or more second subpixels.

### Fourth Embodiment

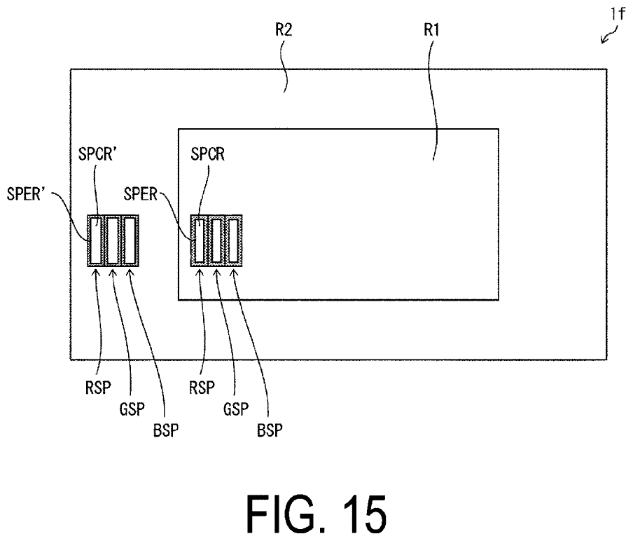

Next, a fourth embodiment of the disclosure will be described with reference to FIG. 15. A display device If of the present embodiment differs from the display devices described in the first to third embodiments in that first light-emitting elements provided in a first region R1 are included in first subpixels, second light-emitting elements provided in the second region R2 are included in second subpixels, a light-emitting layer which is a nanoparticle layer including nanoparticles of the first subpixels and a light-emitting layer which is a nanoparticle layer including nanoparticles of the second subpixels each include inner regions SPCR and SPCR′ and outer regions SPER and SPER′, the outer regions SPER and SPER′ have a higher concentration of halogen atoms than that of the inner regions SPCR and SPCR′, and a ratio of the area of the outer regions SPER and SPER′ to the area of a subpixel is higher in the first subpixels than in the second subpixels. The others are as described in the first to third embodiments. For convenience of description, members having the same functions as those of the members illustrated in the drawings in the first to third embodiments are denoted by the same reference numerals, and descriptions thereof will be omitted.

FIG. 15 is a plan view illustrating an example of the display device If according to the fourth embodiment.

As illustrated in FIG. 15, in the display device 1f, the first light-emitting elements provided in the first region R1 are included in the first subpixels, the second light-emitting elements provided in the second region R2 are included in the second subpixels, the light-emitting layer which is a nanoparticle layer including nanoparticles of the first subpixels and the light-emitting layer which is a nanoparticle layer including nanoparticles of the second subpixels each include the inner regions SPCR and SPCR′ and the outer regions SPER and SPER′, the outer regions SPER and SPER′ have a higher concentration of halogen atoms than that of the inner regions SPCR and SPCR′, and a ratio of the area of the outer regions SPER and SPER′ to the area of a subpixel is higher in the first subpixels than in the second subpixels. By setting the concentration of halogen atoms in the outer regions SPER and SPER′ to be higher than that in the inner regions SPCR and SPCR′, it is possible to protect the light-emitting layer in the peripheral portion of the subpixels from impurities such as water and oxygen.

Thus, in the display device 1f, the concentration of halogen atoms included in the nanoparticle layer provided in one or more light-emitting elements (first light-emitting elements) of the red light-emitting element, green light-emitting element, and blue light-emitting element provided in the first region R1 becomes higher than the concentration of halogen atoms included in the nanoparticle layer provided in one or more light-emitting elements (second light-emitting elements) of the red light-emitting element, green light-emitting element, and blue light-emitting element provided in the second region R2.

In addition, in the display device 1f, two or more second subpixels each including the second light-emitting element may be provided in the second region R2, and the concentration of halogen atoms included in the nanoparticle layer of the second subpixel disposed closer to the first region R1 among the two or more second subpixels may be higher than the concentration of halogen atoms included in the nanoparticle layer of the second subpixel disposed farther from the first region R1 among the two or more second subpixels.

### Fifth Embodiment

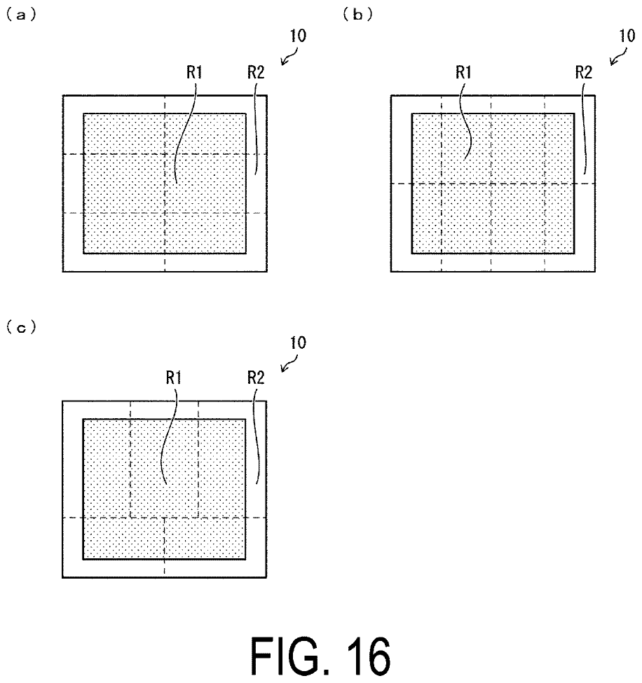

Next, a fifth embodiment of the disclosure will be described with reference to FIG. 16. The method of manufacturing a display device according to the present embodiment is different from those in the first to fourth embodiments in that various display devices can be obtained by varying the cutting position on the same mother substrate. The others are as described in the first to fourth embodiments. For convenience of description, members having the same functions as those of the members illustrated in the drawings in the first to fourth embodiments are denoted by the same reference numerals, and descriptions thereof will be omitted.

(a) to (c) of FIG. 16 are diagrams for describing a method of manufacturing a display device according to the fifth embodiment in which various display devices can be obtained by varying a cutting position on the same mother substrate 10 indicated by the dashed lines in the drawings.

As illustrated in (a) of FIG. 16, six display devices each including a first region R1 and a second region R2 can be obtained by cutting a mother substrate 10 on which the first region R1 and the second region R2 described above are formed into six pieces at the cutting positions indicated by the dashed lines in the drawing.

As illustrated in (b) of FIG. 16, eight display devices each including a first region R1 and a second region R2 can be obtained by cutting the mother substrate 10 on which the first region R1 and the second region R2 described above are formed into eight pieces at the cutting positions indicated by the dashed lines in the drawing.

As illustrated in (c) of FIG. 16, five display devices each including a first region R1 and a second region R2 can be obtained by cutting the mother substrate 10 on which the first region R1 and the second region R2 described above are formed into five pieces at the cutting positions indicated by the dashed lines in the drawing.

### Sixth Embodiment

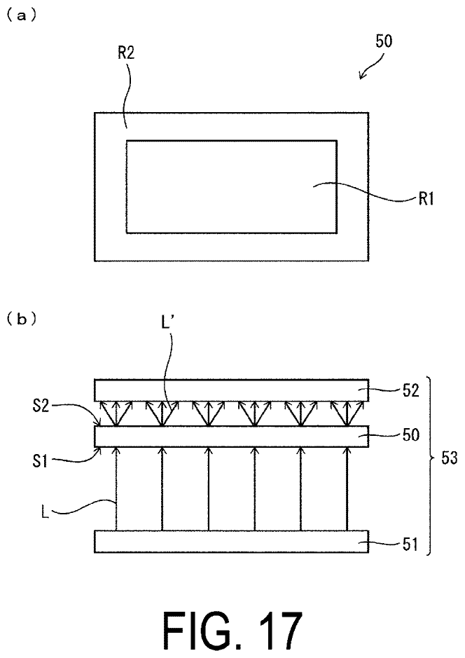

Next, a sixth embodiment of the disclosure will be described with reference to FIG. 17. The display device of the present embodiment is different from the display devices described in the first to fifth embodiments in that the present embodiment is about a light-emitting device 53. The others are as described in the first to fifth embodiments. For convenience of explanation, components having the same functions as those illustrated in diagrams of the first to fifth embodiments are appended with the same reference signs, and descriptions thereof may be omitted.

(a) of FIG. 17 is a plan view illustrating a schematic configuration of a wavelength conversion layer 50 provided in the light-emitting device 53 according to the sixth embodiment, and (b) of FIG. 17 is a cross-sectional view illustrating a schematic configuration of the light-emitting device 53 according to the sixth embodiment.

As illustrated in (a) of FIG. 17, the wavelength conversion layer 50 includes a first region R1 including at least a part of a central portion of the wavelength-converting region and a second region R2 including at least a part of end portions of the wavelength-converting region. The concentration of halogen atoms included in the light-emitting layer including quantum dots in the first region R1 is higher than the concentration of halogen atoms included in the light-emitting layer including quantum dots in the second region R2.

As illustrated in (b) of FIG. 17, the light-emitting device 53 includes a light-emitting portion 51 that is provided on the first surface S1 side of the wavelength conversion layer 50 and emits light incident on the wavelength conversion layer 50, and an emission light amount change portion 52 that is provided on the second surface S2 side of the wavelength conversion layer 50 facing the first surface S1 of the wavelength conversion layer 50 and changes the amount of light to be transmitted emitted from the wavelength conversion layer

Although the case in which the emission light amount change portion 52 that changes the amount of light transmitted, the light being emitted from the wavelength conversion layer 50 is provided is exemplified in the present embodiment, the disclosure is not limited thereto, and the emission light amount change portion 52 may not be provided. According to the light-emitting device 53, it is possible to achieve compatibility of prevention of damage at a site where mechanical stress occurs and high luminous efficiency.

### Seventh Embodiment

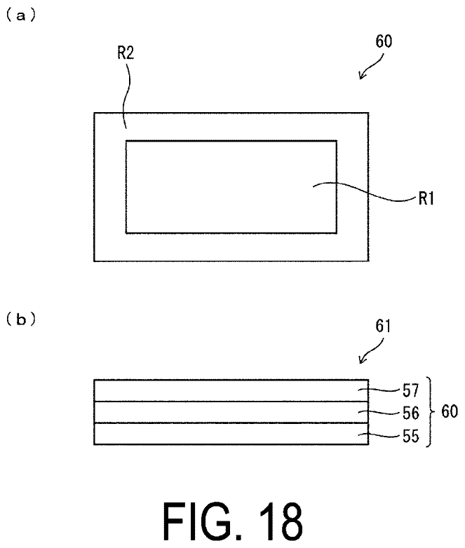

Next, a seventh embodiment of the disclosure will be described with reference to FIG. 18. The present embodiment is different from the display devices described in the first to sixth embodiments in that the present embodiment is about a lighting device 61. The others are as described in the first to sixth embodiments. For convenience of explanation, components having the same functions as those illustrated in diagrams of the first to sixth embodiments are appended with the same reference signs, and descriptions thereof may be omitted.

(a) of FIG. 18 is a plan view illustrating a schematic configuration of a light-emitting region 60 provided in a lighting device 61 according to the seventh embodiment, and (b) of FIG. 18 is a cross-sectional view illustrating a schematic configuration of the lighting device 61 according to the seventh embodiment.

As illustrated in (a) and (b) of FIG. 18, the lighting device 61 includes a light-emitting region 60 having a light-emitting surface in a size of 100 cm² or greater and including a first region R1 including at least a part of a central portion of the light-emitting region 60 and a second region R2 including at least a part of end portions of the light-emitting region 60. The light-emitting region 60 includes first and second electrodes 55 and 57 and a light-emitting layer 56 including quantum dots and provided between the first and second electrodes 55 and 57, and a concentration of halogen atoms included in the first region R1 is higher than a concentration of halogen atoms included in the second region R2.

According to the lighting device 61, it is possible to achieve compatibility of prevention of damage at a site where mechanical stress occurs and high luminous efficiency.

### Appendix

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### INDUSTRIAL APPLICABILITY

The disclosure can be utilized for display devices, light-emitting devices, and lighting devices.

1. A display device comprising:
a display region including a first region including at least a part of a central portion of the display region and a second region including at least a part of an end portion of the display region;
a first light-emitting element provided in the first region; and
a second light-emitting element provided in the second region,
wherein each of the first light-emitting element and the second light-emitting element includes a first electrode and a second electrode, and a nanoparticle layer positioned between the first electrode and the second electrode, the nanoparticle layer including nanoparticles, and
a concentration of halogen atoms included in a first layer which is the nanoparticle layer of the first light-emitting element is higher than a concentration of halogen atoms included in a second layer which is the nanoparticle layer of the second light-emitting element.

2. A display device comprising:
a display region including a first region including at least a part of a central portion of the display region and a second region including at least a part of an end portion of the display region;
a first light-emitting element provided in the first region; and
a second light-emitting element provided in the second region,
wherein each of the first light-emitting element and the second light-emitting element includes a first electrode and a second electrode, and a nanoparticle layer positioned between the first electrode and the second electrode, the nanoparticle layer including nanoparticles,
a central position in a thickness of a maximum film thickness portion of each of a first layer which is the nanoparticle layer of the first light-emitting element and a second layer which is the nanoparticle layer of the second light-emitting element is set as a reference position,
the number of portions of a third layer formed directly above the first layer, the portions intruding into the first layer at or below the reference position, is set as a first number,
the number of portions of a fourth layer formed directly above the second layer, the portions intruding into the second layer at or below the reference position, is set as a second number, and
the first number per unit length of the first layer is greater than the second number per unit length of the second layer.

3. A display device comprising:
a display region including a first region including at least a part of a central portion of the display region and a second region including at least a part of an end portion of the display region;
a first light-emitting element provided in the first region; and
a second light-emitting element provided in the second region,
wherein each of the first light-emitting element and the second light-emitting element includes a first electrode and a second electrode, and a nanoparticle layer positioned between the first electrode and the second electrode, the nanoparticle layer including nanoparticles,
a central position in a thickness of a maximum film thickness portion of each of a third layer formed directly above a first layer which is the nanoparticle layer of the first light-emitting element and a fourth layer formed directly above a second layer which is the nanoparticle layer of the second light-emitting element is set as a reference position,
the number of portions of the first layer, the portions intruding into the third layer at or beyond the reference position, is set as a first number,
the number of portions of the second layer, the portions intruding into the fourth layer at or beyond the reference position, is set as a second number, and
the first number per unit length of the first layer is greater than the second number per unit length of the second layer.

4. The display device according to claim 1,
wherein the first layer and the second layer are light-emitting layers including quantum dots or a charge transfer layer.

5. The display device according to claim 4,
wherein the first layer and the second layer are light-emitting layers including the quantum dots, and
the third layer formed directly above the first layer and the fourth layer formed directly above the second layer are the charge transfer layers.

6. The display device according to claim 4,
wherein the charge transfer layer is any one of a hole transport layer, an electron transport layer, a hole injection layer, and an electron injection layer.

7. The display device according to claim 4,
wherein the first layer and the second layer are hole transport layers, and
each of the third layer formed directly above the first layer and the fourth layer formed directly above the second layer is any one of a light-emitting layer, a hole injection layer, the first electrode, and the second electrode.

8. The display device according to claim 4,
wherein the first layer and the second layer are electron transport layers, and
each of the third layer formed directly above the first layer and the fourth layer formed directly above the second layer is any one of a light-emitting layer, an electron injection layer, the first electrode, and the second electrode.

9. The display device according to claim 4,
wherein the first layer and the second layer are hole injection layers, and
each of the third layer formed directly above the first layer and the fourth layer formed directly above the second layer is one of the first electrode and the second electrode.

10. The display device according to claim 4,
wherein the first layer and the second layer are electron injection layers, and
each of the third layer formed directly above the first layer and the fourth layer formed directly above the second layer is one of the first electrode and the second electrode.

11. (canceled)

12. The display device according to claim 1,
wherein the first light-emitting element and the second light-emitting element are light-emitting elements configured to emit light of the same color.

13-17. (canceled)

18. The display device according to claim 1,
wherein the second region surrounds the first region in a frame shape.

19. The display device according to claim 1, comprising
a substrate having a length in a first direction which is a longitudinal direction and a length in a second direction orthogonal to the first direction, the substrate including the display region
wherein the second region is provided in the second direction closer to each of two of the end portions of the substrate formed in the second direction than the first region.

20. The display device according to claim 1, comprising
a substrate having a length in a first direction which is a longitudinal direction and a length in a second direction orthogonal to the first direction, the substrate including the display region,
wherein the substrate includes a frame portion,
the frame portion is provided in any one of
a first frame region in the second direction, the first frame region including two of the end portions of the substrate formed in the second direction,
a second frame region in the first direction, the second frame region including the two end portions of the substrate formed in the first direction,
a third frame region that is at least two corner portions that are most distant from each other among four corner portions at which the two end portions of the substrate formed in the first direction and the two end portions of the substrate formed in the second direction are in contact with each other, and
a fourth frame region including a portion formed in the first direction and including one of the two end portions of the substrate formed in the first direction, and a portion formed in the second direction and including one of the two end portions of the substrate formed in the second direction.

21. The display device according to claim 19,
wherein the substrate includes a frame portion, and
the frame portion is provided in the second direction closer to each of the two end portions of the substrate formed in the second direction than the second region.

22. The display device according to claim 1, comprising
a substrate having a length in a first direction which is a longitudinal direction and a length in a second direction orthogonal to the first direction, the substrate including the display region,
wherein the second region is provided in the first direction closer to each of two of the end portions of the substrate formed in the first direction than the first region.

23. The display device according to claim 22,
wherein the substrate includes a frame portion, and
the frame portion is provided in the first direction closer to each of the two end portions of the substrate formed in the first direction than the second region.

24. The display device according to claim 1, comprising
a substrate having a length in a first direction which is a longitudinal direction and a length in a second direction orthogonal to the first direction, the substrate including the display region,
wherein the second region is provided at least at two corners that are most distant from each other among four corners at which two corner portion of the end portions of the substrate formed in the first direction and the two end portions of the substrate formed in the second direction are in contact with each other.

25. The display device according to claim 24,
wherein the substrate includes a frame portion, and
the frame portion is provided at the corner portion at which the second region is provided and is provided closer to the corner portion than to the second region.

26. The display device according to claim 1, comprising
a substrate having a length in a first direction which is a longitudinal direction and a length in a second direction orthogonal to the first direction, the substrate including the display region,
wherein the second region includes a portion formed in the first direction close to one of two of the end portions of the substrate formed in the first direction, and a portion formed in the second direction close to one of the two end portions of the substrate formed in the second direction.

27-37. (canceled)
